(19) United States
(12) Patent Application Publication
(10) Pub. No.: US 2025/0323054 A1
(43) Pub. Date: Oct. 16, 2025

(54) SEMICONDUCTOR DEVICE MANUFACTURING METHOD INCLUDING PLASMA ETCHING PROCESS

(71) Applicant: Samsung Electronics Co., Ltd., Suwon-si (KR)

(72) Inventors: Buseo Choi, Suwon-si (KR); Dohoon Kim, Suwon-si (KR); Shingo Nakamura, Osaka-shi (JP); Wonwoong Chung, Suwon-si (KR); Takehiko Kezuka, Osaka-shi (JP); Hana Kim, Suwon-si (KR); Jaeeun Cho, Suwon-si (KR)

(73) Assignee: Daikin Industries, Ltd., Osaka-shi (JP)

(21) Appl. No.: 19/075,978

(22) Filed: Mar. 11, 2025

(30) Foreign Application Priority Data
Apr. 12, 2024 (KR) 10-2024-0049399

(51) Int. Cl. H01L 21/311

(52) U.S. Cl. CPC H01L 21/31116; H01L 21/31144

(57) ABSTRACT

A semiconductor device manufacturing method includes forming an inorganic layer on a support layer, forming organic mask patterns on the inorganic layer, and forming inorganic patterns and space patterns configured to at least partially expose the support layer between the inorganic patterns by performing a plasma etching process on the inorganic layer with the organic mask patterns as an etching mask. The plasma etching process has an etching selectivity that favors the inorganic layer relative to the organic mask patterns. The plasma etching process on the inorganic layer is performed by using a mixed gas including C₂H₂F₄ gas as a main etching gas and O₂ gas or an oxygen-containing gas as an auxiliary etching gas, and a ratio of the main etching gas to the auxiliary etching gas is configured as about 1 to about 5.

### CROSS-REFERENCE TO RELATED APPLICATION

This application is based on and claims priority under 35 U.S.C. § 119 to Korean Patent Application No. 10-2024-0049399, filed Apr. 12, 2024, in the Korean Intellectual Property office, the disclosure of which is incorporated by reference herein in its entirety.

### BACKGROUND

The inventive concept relates to a manufacturing method of a semiconductor device, and more particularly, to a semiconductor device manufacturing method including a plasma etching process.

As semiconductor devices become highly integrated, the critical dimension (CD) of patterns formed on a semiconductor substrate is decreasing. Accordingly, a process of forming fine patterns on the semiconductor substrate is becoming important. A plasma etching process may be introduced to form fine patterns on the semiconductor substrate.

In the plasma etching process, fine patterns may be reliably formed when an etching gas having a high etch selectivity is used. In addition, the global warming potential of the etching gas may need to be lowered from an aspect of global environmental impact.

### SUMMARY

Embodiments of the inventive concept provide a manufacturing method of a semiconductor device in which a plasma etching process is performed by using an etching gas having a high etching selectivity and a low global warming potential.

According to an aspect of the inventive concept, there is provided a manufacturing method of a semiconductor device, the manufacturing method including forming an inorganic layer on a support layer, forming organic mask patterns on the inorganic layer, and forming inorganic patterns and space patterns configured to at least partially expose the support layer between the inorganic patterns by performing a plasma etching process on the inorganic layer with the organic mask patterns as an etching mask. The plasma etching process has an etching selectivity that favors the inorganic layer relative to the organic mask patterns. The plasma etching process on the inorganic layer is performed by using a mixed gas including C₂H₂F₄ gas as a main etching gas and O₂ gas or an oxygen-containing gas as an auxiliary etching gas, and a ratio of the main etching gas to the auxiliary etching gas is configured as about 1 to about 5.

According to another aspect of the inventive concept, there is provided a method of manufacturing a semiconductor device, the method including forming a first organic layer on a support layer, forming first organic patterns by patterning the first organic layer, forming an inorganic layer on the first organic patterns on the support layer, forming inorganic patterns on both sidewalls of the first organic patterns by performing an etchback process on the inorganic layer, forming a second organic layer in spaces between each of the inorganic patterns while being on the first organic patterns and the inorganic patterns, forming second organic patterns between the inorganic patterns by performing an etchback process on the second organic layer, and forming space patterns between the first organic patterns and the second organic patterns by selectively removing the inorganic patterns between the first organic patterns and the second organic patterns by performing a plasma etching process on the inorganic patterns. The plasma etching process has an etching selectivity that favors the inorganic patterns relative to the first organic patterns and the second organic patterns. The plasma etching process on the inorganic patterns is performed by using a mixed gas including C₂H₂F₄ gas as a main etching gas and O₂ gas or an oxygen-containing gas as an auxiliary etching gas, and a ratio of the main etching gas to the auxiliary etching gas is configured as about 1 to about 5.

According to another aspect of the inventive concept, there is provided a method of manufacturing a semiconductor device, the method including forming a first organic layer on a support layer, forming first organic patterns by patterning the first organic layer, forming an inorganic layer on the first organic patterns on the support layer, forming a second organic layer in spaces between each of the first organic patterns while being on the first organic patterns and the inorganic layer on the support layer, forming inorganic patterns and second organic patterns by sequentially etching back the second organic layer and the inorganic layer, wherein the second organic patterns are formed between the inorganic patterns, and the inorganic patterns are formed between the first organic patterns and the second organic patterns, and forming space patterns between the first organic patterns and the second organic patterns by selectively removing the inorganic patterns between the first organic patterns and the second organic patterns by performing a plasma etching process on the inorganic patterns. The plasma etching process has an etching selectivity that favors the inorganic patterns relative to the first organic pattens and the second organic patterns. The plasma etching process on the inorganic layer is performed by using a mixed gas including C₂H₂F₄ gas as a main etching gas and O₂ gas or an oxygen-containing gas as an auxiliary etching gas, and a ratio of the main etching gas to the auxiliary etching gas is configured as about 1 to about 5.

### BRIEF DESCRIPTION OF THE DRAWINGS

Embodiments will be more clearly understood from the following detailed description taken in conjunction with the accompanying drawings in which:

FIG. 1A is a schematic cross-sectional view of an example of a plasma etching apparatus used in a semiconductor device manufacturing method including a plasma etching process, according to an embodiment;

FIG. 1B is a schematic cross-sectional view of an example of a plasma etching apparatus used in a semiconductor device manufacturing method including a plasma etching process, according to an embodiment;

FIG. 2 is a plan view of a semiconductor device according to an embodiment;

FIGS. 3 and 4 are cross-sectional views illustrating a semiconductor device manufacturing method including a fine patterning process, taken along line A-A′ in FIG. 2;

FIG. 5 is a diagram illustrating an etching gas used in the plasma etching process in FIG. 4;

FIG. 6 is a plan view of a semiconductor device according to an embodiment;

FIGS. 7 and 8 are cross-sectional views illustrating a semiconductor device manufacturing method including a fine patterning process, taken along line B-B′in FIG. 6;

FIG. 9 is a plan view of a semiconductor device according to an embodiment;

FIGS. 10 and 11 are cross-sectional views illustrating a semiconductor device manufacturing method including a fine patterning process, taken along line C-C′ in FIG. 9;

FIG. 12 is a diagram illustrating etching selectivities with respect to etching gases in a plasma etching process of an inorganic layer including a silicon oxide layer in a manufacturing method of a semiconductor device, according to an embodiment;

FIG. 13 is a diagram illustrating etching selectivities with respect to etching gases in a plasma etching process of an inorganic layer including a silicon oxide layer in a manufacturing method of a semiconductor device, according to an embodiment;

FIG. 14 is a diagram illustrating etching selectivities with respect to etching gases in a plasma etching process of an inorganic layer including a silicon nitride layer or a silicon oxynitride layer in a manufacturing method of a semiconductor device, according to an embodiment;

FIG. 15 is a diagram illustrating etching selectivities with respect to etching gases in a plasma etching process of an inorganic layer including a silicon nitride layer or a silicon oxynitride layer in a manufacturing method of a semiconductor device, according to an embodiment;

FIG. 16 is a diagram illustrating etching speeds with respect to etching gases in a plasma etching process of an inorganic layer including a silicon oxide layer, a silicon nitride layer, or a silicon oxynitride layer in a manufacturing method of a semiconductor device, according to an embodiment;

FIG. 17 is a plan view of a semiconductor device according to an embodiment;

FIG. 18 is a cross-sectional view of the semiconductor device taken along line D-D′in FIG. 17;

FIGS. 19 through 25 are diagrams for describing a manufacturing method of a semiconductor device, according to embodiments;

FIG. 26 is a plan view of a semiconductor device according to an embodiment;

FIG. 27 is a cross-sectional view of the semiconductor device taken along line E-E′ in FIG. 26;

FIG. 28 is a plan view of a semiconductor device according to an embodiment;

FIG. 29 is a cross-sectional view of the semiconductor device taken along line F-F′ in FIG. 28; and

FIGS. 30 through 32 are cross-sectional views for describing a manufacturing method of a semiconductor device, according to embodiments.

### DETAILED DESCRIPTION OF THE EMBODIMENTS

Hereinafter, embodiments of the present disclosure will be described as follows with reference to the accompanying drawings in which example embodiments of the inventive concept are shown. The same reference numerals are used for the same elements in the drawings, and redundant descriptions thereof will be omitted. As used herein, the term “and/or” includes any and all combinations of one or more of the associated listed items. It will be understood that when an element is referred to as being “on,” “attached” to, “connected” to, “coupled” with, “contacting,” etc., another element, it can be directly on, attached to, connected to, coupled with or contacting the other element or intervening elements may also be present. In contrast, when an element is referred to as being, for example, “directly on,” “directly attached” to, “directly connected” to, “directly coupled” with or “directly contacting” another element, there are no intervening elements present. In embodiments of the inventive concept, a singular form of the constituent components may include a plural form unless the context clearly indicates otherwise. In the present specification, the drawings are exaggerated for clarifying embodiments of the inventive concept. It is noted that aspects described with respect to one embodiment may be incorporated in different embodiments although not specifically described relative thereto. That is, all embodiments and/or features of any embodiments can be combined in any way and/or combination.

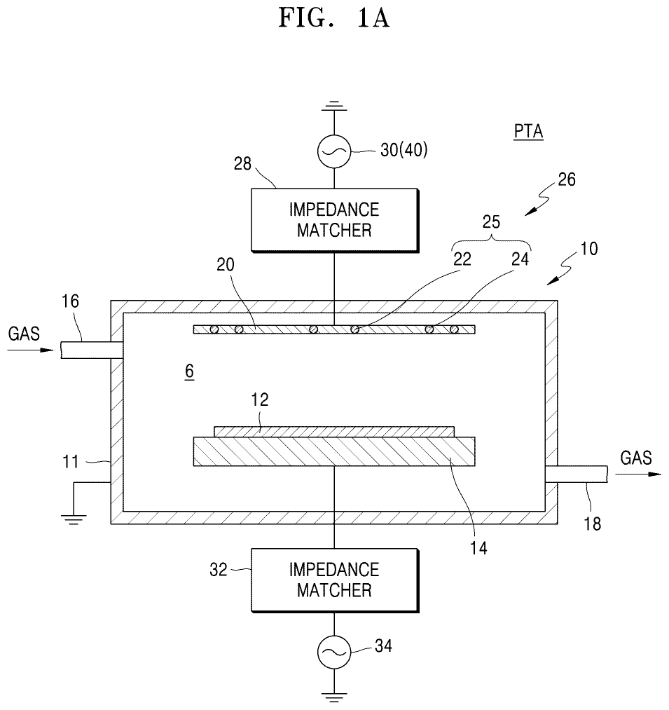

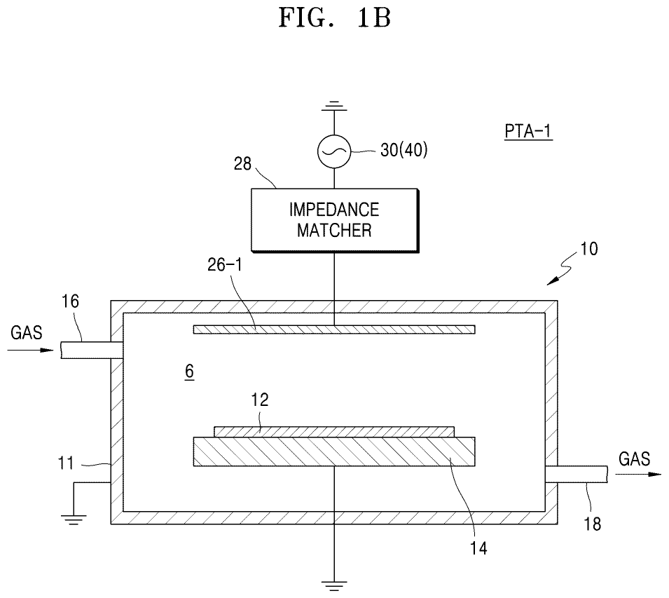

FIG. 1A is a schematic cross-sectional view of an example of a plasma etching apparatus PTA used in a semiconductor device manufacturing method including a plasma etching process, according to an embodiment.

As an example of the plasma etching apparatus PTA, an inductively coupled plasma (ICP) etching apparatus may be a representative embodiment. The plasma etching apparatus PTA may include a processing chamber 10 having a gas inlet 16 and a gas outlet 18.

The processing chamber 10 may include an internal space 6. The internal space 6 may include a processing chamber for plasma etching. The processing chamber 10 may be grounded. A process gas, for example, an etching gas, may be introduced into the processing chamber 10 through the gas inlet 16 and may be discharged to the outside through the gas outlet 18. The processing chamber 10 may be maintained at a high vacuum to reduce or prevent process defects that may be caused by contaminants such as particles during the plasma etching.

In the processing chamber 10, a high frequency electrode unit 26 and an electrostatic chuck 14 may be installed. The high frequency electrode unit 26 and the electrostatic chuck 14 may be used as a first electrode and a second electrode, respectively, and may be installed to face each other. The high frequency electrode unit 26 may be installed on a dielectric window 20 above the processing chamber 10. The high frequency electrode unit 26 may include high frequency antennas 25.

The high frequency antennas 25 may include an internal antenna 22 corresponding to a center portion of a substrate 12 and an external antenna 24 arranged outside the internal antenna 22 and corresponding to a corner portion of the substrate 12. A high frequency power source 30 applying high frequency electricity (power), that is, radio frequency (RF) electricity, may be connected to the high frequency electrode unit 26 via an impedance matcher 28.

The high frequency power applied via the high frequency power source 30 may include power having a frequency of about 27 MHz or higher. For example, the high frequency power applied via the high frequency power source 30 may include power having a frequency of about 60 MHz. When the high frequency antennas 25 are configured as the internal antenna 22 and the external antenna 24, the magnetic field may be precisely controlled to make the plasma density on the substrate 12 substantially uniform.

The substrate 12, for example, a wafer, may be mounted on the electrostatic chuck 14. The wafer may include a wafer having a diameter of about 300 mm. The wafer may include a silicon wafer. A bias power source 34 for applying high frequency power via an impedance matcher 32 may be connected to the electrostatic chuck 14.

The high frequency power applied via the bias power source 34 may include power having a frequency of about 100 KHz to about 10 MHz. For example, the high frequency power applied via the bias power source 34 may include power having a frequency of about 2 MHz. The impedance matchers 28 and 32 may not be installed as necessary in some embodiments.

The process gas injected into the processing chamber 10, that is, the etching gas, may be plasmaized by a plasma applicator 40. The plasma applicator 40 may include the high frequency power source 30 electrically connected to the high frequency electrode unit 26.

When power is applied to the high frequency electrode unit 26 via the high frequency power source 30, the process gas injected into the processing chamber 10 may be plasmaized. When high frequency power or low frequency power is applied to the electrostatic chuck 14 via the bias power source 34, the plasma generated in the processing chamber 10 may be better guided toward the substrate 12.

FIG. 1B is a schematic cross-sectional view of an example of a plasma etching apparatus PTA-1 used in a semiconductor device manufacturing method including a plasma etching process, according to an embodiment.

As an example of the plasma etching apparatus PTA-1, a charge coupled plasma (CCP) etching apparatus may be a representative embodiment. The plasma etching apparatus PTA-1 may be the same as the plasma etching apparatus PTA of FIG. 1 except that a high frequency electrode unit 26-1 includes a flat plate electrode and the electrostatic chuck 14 is grounded. In FIG. 1B, the same reference numerals as those in FIG. 1A may represent the same members.

The plasma etching apparatus PTA-1 may include the processing chamber 10 where the gas inlet 16 and the gas outlet 18. The processing chamber 10 may include an internal space 6. The internal space 6 may include a processing chamber for plasma etching.

In the processing chamber 10, the high frequency electrode unit 26-1 and the electrostatic chuck 14 may be installed. The plasma etching apparatus PTA-1 may use a flat plate electrode as the high frequency electrode unit 26-1.

The process gas injected into the processing chamber 10, that is, the etching gas, may be plasmaized by the plasma applicator 40. The plasma applicator 40 may include the high frequency power source 30 electrically connected to the high frequency electrode unit 26-1. When power is applied to the high frequency electrode unit 26-1 via the high frequency power source 30, the process gas injected into the processing chamber 10 may be plasmaized.

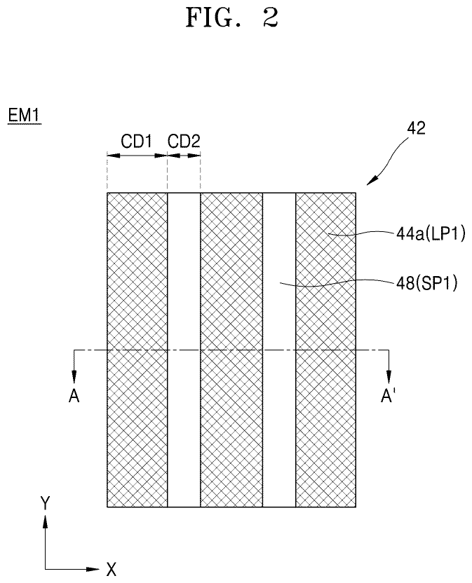

FIG. 2 is a plan view of a semiconductor device EM1 according to an embodiment.

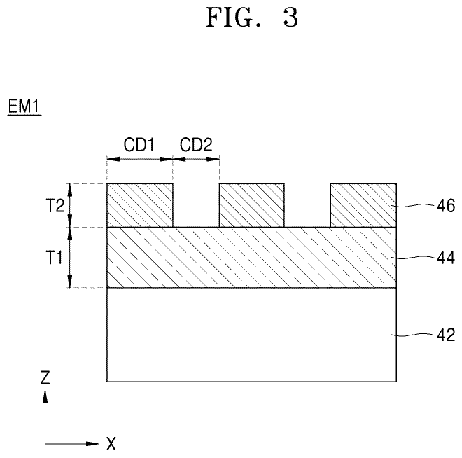

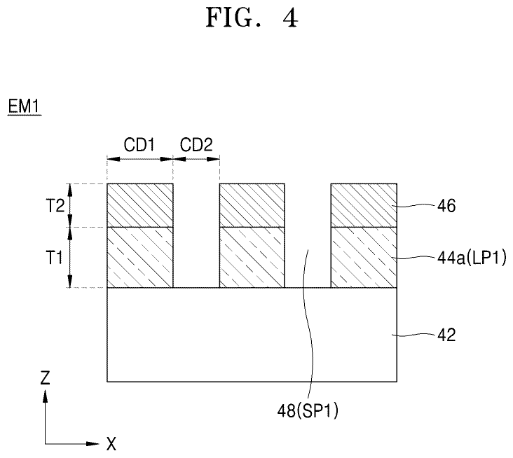

The semiconductor device EM1 may include inorganic patterns 44a and space patterns 48 arranged on a support layer (42 in FIGS. 3 and 4). The inorganic patterns 44a and the space patterns 48 may be formed by using a manufacturing method of the semiconductor device EM1 including the plasma etching process, as described below. A manufacturing method of a semiconductor device may include a fine patterning process.

The inorganic patterns 44a may include a plurality of patterns spaced apart from each other on the support layer (42 in FIGS. 3 and 4) in a first direction (X direction). In some embodiments, the inorganic patterns 44a may include a single layer of a silicon oxide layer. In some embodiments, the inorganic patterns 44a may include a single layer of a silicon nitride (SiN) layer or a silicon oxynitride (SiON) layer.

The inorganic patterns 44a may have a first critical dimension CD1 in the first direction (X direction). In some embodiments, the first critical dimension CD1 may be several nm to several tens of nm. In some embodiments, the first critical dimension CD1 may be about 20 nm or less. In some embodiments, the first critical dimension CD1 may be about 2 nm to about 20 nm.

The inorganic patterns 44a may include patterns extending in a second direction (Y direction) perpendicular to the first direction (X direction) in a plan view of the semiconductor device EM1. In FIG. 2, for convenience, only three inorganic patterns 44a are illustrated in the first direction (X direction), but more inorganic patterns 44a may be arranged. The inorganic patterns 44a may include line-type patterns LP1 in a plan view of the semiconductor device EM1.

The space patterns 48 may be arranged between the inorganic patterns 44a. The space patterns 48 may include a plurality of patterns spaced apart from each other on the support layer (42 in FIGS. 3 and 4) in the first direction (X direction). The space patterns 48 may have a second critical dimension CD2 in the first direction (X direction).

In some embodiments, the second critical dimension CD2 may be several nm to several tens of nm. In some embodiments, the second critical dimension CD2 may be about 20 nm or less. In some embodiments, the second critical dimension CD2 may be about 2 nm to about 20 nm.

The space patterns 48 may include patterns extending in the second direction (Y direction) perpendicular to the first direction (X direction) in a plan view. The space patterns 48 may include line-type space patterns SP1 in a plan view.

In some embodiments, the first critical dimension CD1 of the inorganic patterns 44a and the second critical dimension CD2 of the space patterns 48 may be the same as each other. In some embodiments, the first critical dimension CD1 of the inorganic patterns 44a and the second critical dimension CD2 of the space patterns 48 may be different from each other.

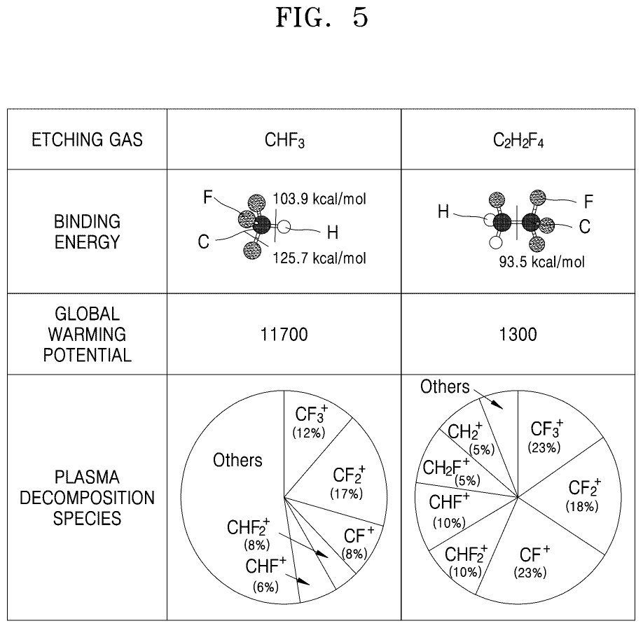

FIGS. 3 and 4 are cross-sectional views illustrating a manufacturing method of a semiconductor device EM1 including a fine patterning process, taken along line A-A′ in FIG. 2, and FIG. 5 is a diagram illustrating an etching gas used in the plasma etching process in FIG. 4.

Referring to FIG. 3, the manufacturing method of the semiconductor device EM1 may include forming an inorganic layer 44 on a support layer 42. The support layer 42 may include a substrate. The support layer 42 may correspond to the substrate 12 in FIGS. 1A and 1B. A substrate may include a semiconductor such as, Si and/or Ge, or a compound semiconductor, such as SiGe, SiC, GaAs, InAs, and/or InP. In some embodiments, the substrate may include a Group III-V material or a Group IV material, or a combination of a Group II-V material and a Group IV material.

The Group III-V material may include a compound including, as a Group III element, In, Ga, and/or Al, and as a Group V element, As, P, and/or Sb. The Group IV material may include Si or Ge. In some embodiments, the substrate may have a silicon-on-insulator (SOI) structure.

In some embodiments, the inorganic layer 44 may include a single layer of a silicon oxide layer. In some embodiments, the inorganic layer 44 may include a single layer of the SiN layer or the SiON layer. In some embodiments, the inorganic layer 44 may be formed to have a thickness T1. In some embodiments, the thickness T1 may be formed as tens of μm to hundreds of μm.

Organic mask patterns 46 may be formed on the inorganic layer 44. The organic mask patterns 46 may be formed by using a photo-etching process after an organic layer is formed on the inorganic layer 44. The organic mask patterns 46 are formed to have a thickness of T2. In some embodiments, the thickness T2 may be formed as several nm to hundreds of nm or as several μm to hundreds of μm.

In some embodiments, the organic mask patterns 46 may include a spin on hard mask (SOH) material. The SOH material may be referred to as a material including a hydrocarbon compound having a relatively high carbon content of about 85 wt % to about 99 wt % based on the total weight of carbon, or a material including derivatives of the hydrocarbon compound.

In some embodiments, the organic mask patterns 46 may include an amorphous carbon layer (ACL) material or a photoresist material. The ACL material and the photoresist material may also contain a large amount of carbon, and thus they may have similar properties to the SOH material. The organic mask patterns 46 may have the first critical dimension CD1 in the first direction (X direction). Space portions between each of the organic mask patterns 46 may have a second critical dimension CD2.

Referring to FIG. 4, the inorganic patterns 44a and space patterns 48 may be formed by using a plasma etching process on an inorganic layer (44 in FIG. 3) with the organic mask patterns 46 as etching masks. The inorganic patterns 44a may include patterns extending vertically on the support layer 42 in a third direction (Z direction) perpendicular to the first direction (X direction). The inorganic patterns 44a may have the first critical dimension CD1 in the first direction (X direction). The inorganic patterns 44a may include line-type patterns LP1 on the support layer 42 in a plan view of the semiconductor device EM1.

The space patterns 48 may be formed between the inorganic patterns 44a in the first direction (X direction) and may expose the support layer 44. The space patterns 48 may include line-type space patterns SP1 on the support layer 42 in a plan view. The space patterns 48 may have the second critical dimension CD2 in the first direction (X direction).

The inorganic patterns 44a and the space patterns 48 may be formed by using a plasma etching process on the inorganic layer (44 in FIG. 3) by using the plasma etching apparatus PTA of FIG. 1A or the plasma etching apparatus PTA-1 of FIG. 1B.

To increase the etch selectivity of the inorganic layer (44 in FIG. 3) with respect to the organic mask patterns 46 and decrease the global warming potential during the plasma etching process, a mixture gas, in which C₂H₂F₄ gas is used as the main etching gas, and O₂ gas or an oxygen-containing gas is used as the auxiliary etching gas, may be used. In some embodiments, the oxygen-containing gas may include CO₂, CO, COF₂, SO₂, H₂O, NO, NO₂, and/or N₂O. The oxygen-containing gas may not be limited to the molecular structure of the gases presented above, as long as the gases contain oxygen to generate oxygen plasma. In some embodiments, the plasma etching process may be performed by further including CF₄ gas, C₄F₈ gas, and Ar gas in a main etching gas.

When C₂H₂F₄ gas is decomposed by plasma, plasma decomposition species (or plasma dissociation species), such as CFₓ and CHFₓ, may be mainly generated. The plasma decomposition species may etch the inorganic layer by generating a volatile material, such as SiFₓ and/or CO₂, in the silicon oxide layer, which is the inorganic layer (44 in FIG. 3). The plasma decomposition species may etch the inorganic layer (44 in FIG. 3) by generating volatile substances, such as SiFₓ, NH₃, and HCN, in the SiN layer or a silicon oxynitride (SiON) layer, which is the inorganic layer (44 in FIG. 3).

In this case, etching characteristics of C₂H₂F₄ gas used as the main etching gas in the plasma etching process in some embodiments of the inventive concept is described in detail with reference to FIG. 5. To describe the etching characteristics of C₂H₂F₄ gas, the etching characteristics of CHF₃ gas is described together as a comparative example.

Firstly, the CHF₃ gas of the comparative example may be combined in the same form as that of F—CF₂—H. The binding energy between CF₂ and F may be about 125.7 kcal/mol, and the binding energy between CF₂ and H may be about 101.7 kcal/mol. On the other hand, C₂H₂F₄ gas may be bonded in the same form as that of CH₃—CH₂F. The binding energy between CH₃ and CH₂F may be about 93.5 kcal/mol.

From this standpoint, C₂H₂F₄ gas may have lower binding energy than CHF₃ gas. In other words, the binding energy of atoms or molecules constituting the C₂H₂F₄ gas may be lower than the binding energy of atoms or molecules constituting the CHF₃ gas.

Accordingly, C₂H₂F₄ gas may be plasmaized better than CHF₃ gas, which is advantageous for etching the inorganic layer (44 in FIG. 3). In other words, the C₂H₂F₄ gas may generate plasma etching species having a higher concentration than the CHF₃ gas to further increase the etching reaction speed, and thus, may effectively etch the inorganic layer (44 in FIG. 3).

As a result, when C₂H₂F₄ gas is used as an etching gas during the plasma etching, the etching selectivity defined as a ratio of the thickness T1 of the inorganic patterns 44a to the thickness T2 of the organic mask patterns 46 may be increased. That is, the etching gas favors etching of the inorganic patterns 44a relative to the organic mask patterns 46.

Secondly, the global warming potential may be as high as about 11700 because CHF₃ gas does not decompose well and tends to stay in the atmosphere for a long time due to its high binding energy as described above. The global warming potential may be an indicator to estimate a magnitude of a global warming effect compared to CO₂ by standardizing the global warming effect of one molecule of CO₂ to 1. Because the global warming potential of CHF₃ gas is about 11700, the CHF₃ gas may be a material with a relatively high greenhouse effect.

On the other hand, as described above, C₂H₂F₄ gas may be well decomposed in the air due to low binding energy, and the global warming potential may be reduced to about 1300. Accordingly, the C₂H₂F₄ gas may have less impact on the global warming than the CHF₃ gas.

Thirdly, when the CHF₃ gas and the C₂H₂F₄ gas are plasmaized, CF₃⁺, CF₂⁺, and CF⁺, which are etching species of the silicon oxide layer constituting the inorganic layer 44, may occur, and CHF₂⁺ and CHF⁺, which are etching species of the SiN layer or the SiON layer constituting the inorganic layer 44, may occur.

When the CHF₃ gas is plasmaized, compared to the case when the C₂H₂F₄ gas is plasmaized, ratios of CF₃⁺, CF₂⁺, and CF⁺, which are etching species of the silicon oxide layer constituting the inorganic layer 44, and ratios of CHF₂⁺ and CHF⁺, which are etching species of the SiN layer or the SiON layer constituting the inorganic layer 44, may be higher. Accordingly, the C₂H₂F₄ gas, compared to the CHF₃ gas, may increase the etching speed of the silicon oxide layer, the SiN layer, or the SiON layer constituting the inorganic layer (44 in FIG. 3).

As a result, when the C₂H₂F₄ gas is used as an etching gas during the plasma etching, the etching selectivity defined as a ratio of the thickness T1 of the inorganic patterns 44a to the thickness T2 of the organic mask patterns 46 may be increased. That is, the etching gas favors etching of the inorganic patterns 44a relative to the organic mask patterns 46.

Fourthly, when the C₂H₂F₄ gas is plasmaized, CH₂F+and CH₂⁺, that are mask protection species, protecting the organic mask patterns 46. In some embodiments, in addition to CH₂F⁺ and CH₂⁺, CH⁺ may occur as a mask protection species.

Accordingly, a mask protection layer may be further formed on the organic mask patterns 48 during the plasma etching process on the inorganic layer (44 in FIG. 3). As a result, when C₂H₂F₄ gas is used as an etching gas during the plasma etching, the etching selectivity defined as a ratio of the thickness T1 of the inorganic patterns 44a to the thickness T2 of the organic mask patterns 46 may be increased. That is, the etching gas favors of etching the inorganic patterns 44a relative to the organic mask patterns 46

As stated above, an advantage that occurs when the C₂H₂F₄ gas is used as a main etching gas during plasma etching of the inorganic layer (44 in FIG. 3) has been described. In addition, an advantage that occurs when the O₂ gas is used as an auxiliary etching gas during plasma etching of the inorganic layer (44 in FIG. 3) is described in detail below.

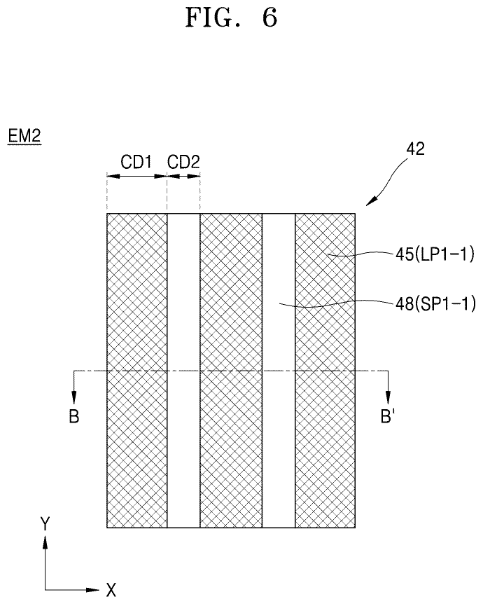

FIG. 6 is a plan view of a semiconductor device EM2 according to an embodiment.

The semiconductor device EM2, compared to the semiconductor device EM1 of FIG. 2, may be the same as the semiconductor device EM1 except that the inorganic patterns 45 include double layers of first inorganic patterns and second inorganic patterns. In FIG. 6, descriptions given with reference to FIG. 2 are briefly described or omitted.

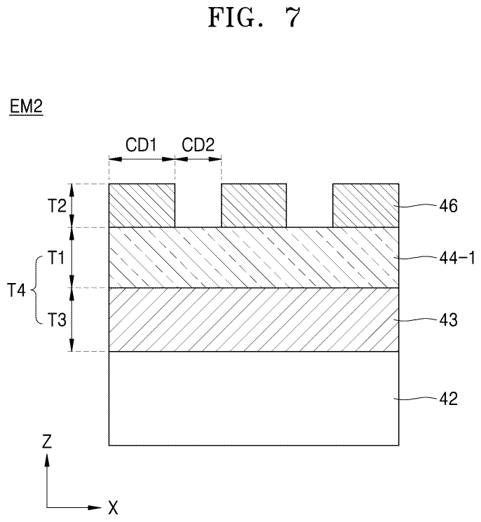

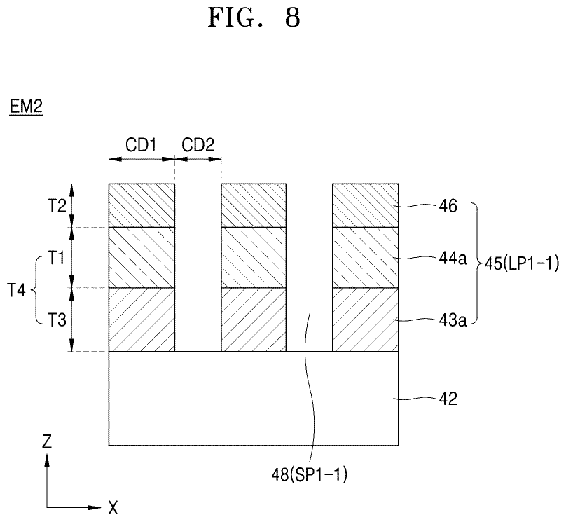

The semiconductor device EM2 may include the inorganic patterns 45 and space patterns 48 arranged on a support layer (42 in FIGS. 7 and 8). The inorganic patterns 45 and the space patterns 48 may be formed by using a manufacturing method of the semiconductor device EM2 including the plasma etching process, as described below. A manufacturing method of a semiconductor device may include a fine patterning process.

The inorganic patterns 45 may include a plurality of patterns spaced apart from each other on the support layer (42 in FIGS. 7 and 8) in the first direction (X direction). In some embodiments, the inorganic patterns 45 may include a double layer of the first inorganic patterns including the SiN layer or the SiON layer, and the second inorganic patterns including the silicon oxide layer. The inorganic patterns 45 may have the first critical dimension CD1 in the first direction (X direction).

The inorganic patterns 45 may include patterns extending in the second direction (Y direction) perpendicular to the first direction (X direction) in a plan view. The inorganic patterns 45 may include line-type patterns LP1-1 in a plan view of the semiconductor device EM2.

The space patterns 48 may be arranged between the inorganic patterns 45. The space patterns 48 may include a plurality of patterns spaced apart from each other on the support layer (42 in FIGS. 7 and 8) in the first direction (X direction). The space patterns 48 may have the second critical dimension CD2 in the first direction (X direction).

The space patterns 48 may include patterns extending in the second direction (Y direction) perpendicular to the first direction (X direction) in a plan view of the semiconductor device EM2. The space patterns 48 may include line-type space patterns SP1-1 in a plan view of the semiconductor device EM2.

FIGS. 7 and 8 are cross-sectional views illustrating a manufacturing method of the semiconductor device EM2 including a fine patterning process, taken along line B-B′ in FIG. 6.

The manufacturing method of the semiconductor device EM2 may, compared with the manufacturing method of the semiconductor device EM1 of FIGS. 3 through 5, may be the same except that the inorganic patterns 45 are formed by using a double layer of the first inorganic patterns 43a and the second inorganic patterns 44a. In FIGS. 7 and 8, descriptions given with reference to FIGS. 3 and 4 are briefly described or omitted.

Referring to FIG. 7, the manufacturing method of the semiconductor device EM2 may include forming a first inorganic layer 43 on the support layer 42. The support layer 42 may include a substrate. In some embodiments, the first inorganic layer 43 may include the SiN layer or the SiON layer. In some embodiments, the first inorganic layer 43 may be formed to have a thickness T3. In some embodiments, the thickness T3 may be formed as several nm to hundreds of nm or as several μm to hundreds of μm.

A second inorganic layer 44-1 may be formed on the first inorganic layer 43. In some embodiments, the second inorganic layer 44-1 may be formed by a silicon oxide layer. In some embodiments, the second inorganic layer 44-1 may be formed to have the thickness T1. The first inorganic layer 43 and the second inorganic layer 44-1 may have a thickness of T4 in general. In some embodiments, the thickness T4 may be formed as several nm to hundreds of nm or as several μm to hundreds of μm.

Organic mask patterns 46 may be formed on the second inorganic layer 44-1. The organic mask patterns 46 may be formed by using a photo-etching process after an organic layer is formed on the second inorganic layer 44-1. The organic mask patterns 46 may be formed to have the thickness of T2.

In some embodiments, the organic mask patterns 46 may include an SOH material. In some embodiments, the organic mask patterns 46 may include an ACL material or a photoresist material. The ACL material and the photoresist material may also contain a large amount of carbon, and thus they may have similar properties to the SOH material.

The organic mask patterns 46 may have the first critical dimension CD1 in the first direction (X direction). Space portions between each of the organic mask patterns 46 may have a second critical dimension CD2.

Referring to FIG. 8, the second inorganic layer (44-1 in FIG. 7) and the first inorganic layer (43 in FIG. 7) may be plasma-etched by using the organic mask patterns 46 to form the inorganic patterns 45 and the space patterns 48. The inorganic patterns 45 may include first inorganic patterns 43a and second inorganic patterns 44a. The first inorganic patterns 43a may include silicon nitride patterns. The second inorganic patterns 44a may include silicon oxide patterns.

The inorganic patterns 44a may include patterns extending vertically on the support layer 42 in the third direction (Z direction) perpendicular to the first direction (X direction). The inorganic patterns 45 may have the first critical dimension CD1 in the first direction (X direction). The inorganic patterns 45 may include the line-type patterns LP1-1 on the support layer 42 in a plan view of the semiconductor device EM2.

The space pattern 48 may be formed between each of the inorganic patterns 45 in the first direction (X direction) and may expose the support layer 42. The space patterns 48 may include the line-type space patterns SP1-1 on the support layer 42 in a plan view of the semiconductor device EM2. The space patterns 48 may have a second critical dimension CD2 in the first direction (X direction).

The inorganic patterns 45 and the space patterns 48 may be formed by using a plasma etching process on the second inorganic layer (44-1 in FIG. 7) and the first inorganic layer (43 in FIG. 7) by using the plasma etching apparatus PTA of FIG. 1A or the plasma etching apparatus PTA-1 of FIG. 1B. During the plasma etching process, an etching gas is used for increasing the etch selectivity of the second inorganic layer (44-1 in FIG. 7) and the first inorganic layer (43 in FIG. 7) with respect to the organic mask patterns 46 and reducing the global warming potential. That is, the etching gas favors etching of second inorganic layer 44-1 and the first inorganic layer 43 relative to the organic mask patterns 46

The etching gas uses a mixed gas using the C₂H₂F₄ gas as a main etching gas and the O₂gas or an oxygen-containing gas as an auxiliary etching gas. In some embodiments, the oxygen-containing gas may include CO₂, CO, COF₂, SO₂, H₂O, NO, NO₂, and/or N₂0. The oxygen-containing gas may not be limited to the molecular structure of the gases presented above, as long as the gases contain oxygen to generate oxygen plasma. In some embodiments, the plasma etching process may be performed by further including CF₄ gas, C₄F₈ gas, and/or Ar gas in the main etching gas.

The advantage of using the C₂H₂F₄ gas as the main etching gas is described above with reference to FIG. 5, and thus the same description thereof is omitted herein.

Additionally, when the C₂H₂F₄ gas is plasmaized, ratios of CF₃⁺, CF₂⁺, and CF⁺, which are etching species of the silicon oxide layer constituting the second inorganic layer (44-1 in FIG. 77) may be higher than ratios of CHF₂⁺ and CHF⁺, which are etching species of the SiN layer or the SiON layer constituting the first inorganic layer (43 in FIG. 7).

When configured in this manner, the etching speeds of the second inorganic layer (44-1 in FIG. 7) including the silicon oxide layer and the first inorganic layer (43 in FIG. 7) including the SiN layer or the SiON layer may be controlled to be substantially uniform. Accordingly, when C₂H₂F₄ gas is used as the etching gas during the plasma etching process, the etching selectivity defined as the ratio of the thickness T4 of the inorganic patterns 45 to the thickness T2 of the organic mask patterns 46 may be increased. That is, the etching gas favors etching of the inorganic patterns 45 relative to the organic mask patterns 46.

In addition, the advantage of using the O₂ gas as an auxiliary etching gas during the plasma etching process on the second inorganic layer (44-1 in FIG. 7) and the first inorganic layer (43 in FIG. 7) is described in detail below.

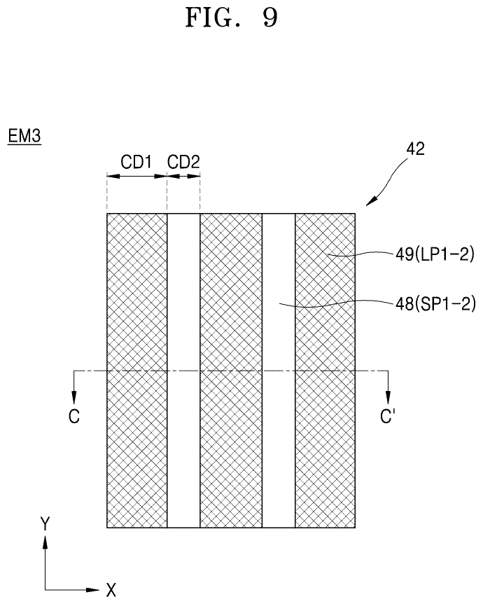

FIG. 9 is a plan view of a semiconductor device EM3 according to an embodiment.

The semiconductor device EM3 may be, when compared to the semiconductor device EM1 of FIG. 2, the same as the semiconductor device EM1 except that inorganic patterns 49 include triple layers of first inorganic patterns 43a, second inorganic patterns 44a, and third inorganic patterns 47a. In FIG. 9, descriptions given with reference to FIG. 2 are briefly described or omitted.

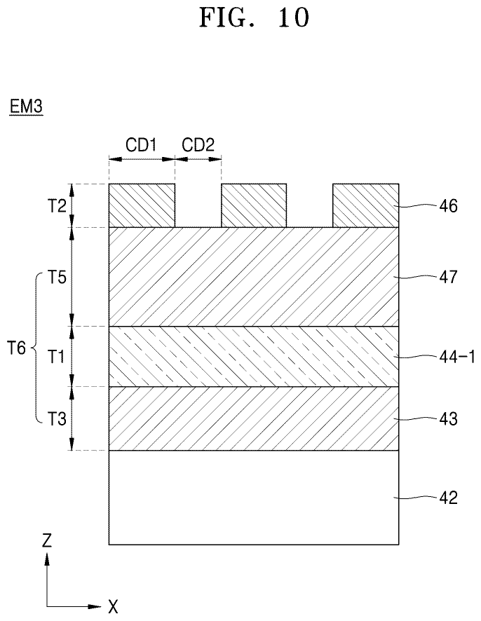

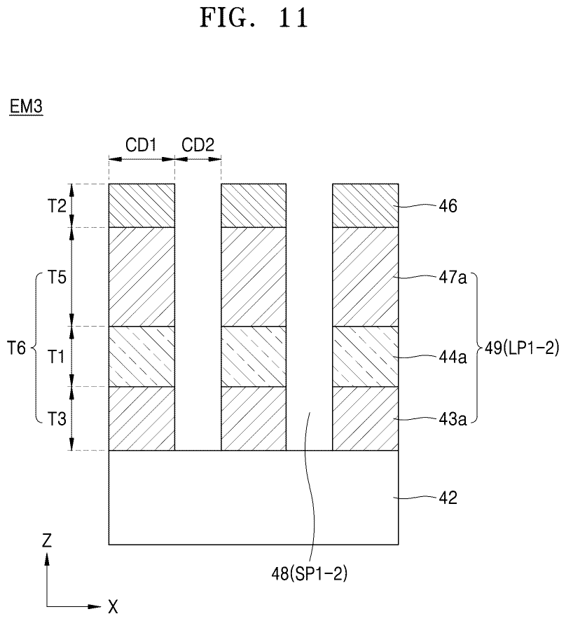

The semiconductor device EM3 may include the inorganic patterns 49 and the space patterns 48 arranged on the support layer (42 in FIGS. 10 and 11). The inorganic patterns 49 and the space patterns 48 may be formed by using a manufacturing method of the semiconductor device EM3 including the plasma etching process, as described below. A manufacturing method of a semiconductor device may include a fine patterning process.

The inorganic patterns 49 may include a plurality of patterns spaced apart from each other on the support layer (42 in FIGS. 10 and 11) in the first direction (X direction). In some embodiments, the inorganic patterns 49 may include a triple layer of the first inorganic patterns including the SiN layer or the SiON layer, the second inorganic patterns including the silicon oxide layer, and the third inorganic patterns including the silicon oxide layer. The inorganic patterns 49 may have the first critical dimension CD1 in the first direction (X direction).

The inorganic patterns 49 may include patterns extending in the second direction (Y direction) perpendicular to the first direction (X direction) in a plan view. The inorganic patterns 49 may include the line-type patterns LP1-1 in a plan view.

The space patterns 48 may be arranged between the inorganic patterns 49. The space patterns 48 may include a plurality of patterns spaced apart from each other on the support layer (42 in FIGS. 10 and 11) in the first direction (X direction). The space patterns 48 may have the second critical dimension CD2 in the first direction (X direction).

The space patterns 48 may include patterns extending in the second direction (Y direction) perpendicular to the first direction (X direction) in a plan view. The space patterns 48 may include the line-type space patterns SP1-1 in a plan view of the semiconductor device EM3.

FIGS. 10 and 11 are cross-sectional views illustrating a manufacturing method of the semiconductor device EM3 including a fine patterning process, taken along line C-C′ in FIG. 9.

The manufacturing method of the semiconductor device EM3 may, when compared with the manufacturing method of the semiconductor device EM1 of FIGS. 3 through 5, be the same except that the inorganic patterns 45 are formed by using a triple layer of the first inorganic patterns 43a, the second inorganic patterns 44a, and the third inorganic patterns 47a. In FIGS. 10 and 11, descriptions given with reference to FIGS. 3 and 4 are briefly described or omitted.

Referring to FIG. 10, the manufacturing method of the semiconductor device EM3 may include forming the first inorganic layer 43 on the support layer 42. The support layer 42 may include a substrate. In some embodiments, the first inorganic layer 43 may include the SiN layer or the SiON layer. In some embodiments, the first inorganic layer 43 may be formed to have the thickness T3. In some embodiments, the thickness T3 may be formed as several nm to hundreds of nm or as several μm to hundreds of μm.

The second inorganic layer 44-1 may be formed on the first inorganic layer 43. In some embodiments, the second inorganic layer 44-1 may be formed by using the silicon oxide layer. In some embodiments, the second inorganic layer 44-1 may be formed to have the thickness T1.

The second inorganic layer 44-1 may be formed on a third inorganic layer 47. The third inorganic layer 47 may be formed thicker than the second inorganic layer 44-1. The third inorganic layer 47 may include a silicon oxide layer having a different forming method or source material from the second inorganic layer 44-1. For example, the second inorganic layer 44-1 may include a silicon oxide layer formed by using tetraethyl orthosilicate (TEOS), and the third inorganic layer 47 may include a silicon oxide layer formed by using SᵢH₄ gas and O₂ gas.

In some embodiments, the third inorganic layer 47 may be formed to have a thickness T5. In some embodiments, the thickness T5 may be formed as several nm to hundreds of nm or as several μm to hundreds of μm. The first inorganic layer 43, the second inorganic layer 44-1, and the third inorganic layer may have a thickness of T6 in general. In some embodiments, the thickness T6 may be several nm to hundreds of nm or several μm to hundreds of μm.

The organic mask patterns 46 may be formed on the second inorganic layer 44-1. The organic mask patterns 46 may be formed by using a photo-etching process, after an organic layer is formed on the second inorganic layer 44-1. The organic mask patterns 46 are formed to have the thickness of T2.

In some embodiments, the organic mask patterns 46 may include the SOH material. In some embodiments, the organic mask patterns 46 may include the ACL material or a photoresist material. The ACL material and the photoresist material may also contain a large amount of carbon, and thus they may have similar properties to the SOH material.

The organic mask patterns 46 may have the first critical dimension CD1 in the first direction (X direction). Space portions between each of the organic mask patterns 46 may have the second critical dimension CD2.

Referring to FIG. 11, the third inorganic layer (47 in FIG. 10), the second inorganic layer (44-1 in FIG. 10), and the first inorganic layer (43 in FIG. 10) may be plasma-etched by using the organic mask patterns 46 to form the inorganic patterns 49 and the space patterns 48.

The inorganic patterns 49 may include the first inorganic patterns 43a, the second inorganic patterns 44a, and the third inorganic patterns 47a. The first inorganic patterns 43a may include silicon nitride patterns. The second inorganic patterns 44a and the third inorganic patterns 47a may be silicon oxide patterns.

The inorganic patterns 49 may include patterns extending vertically on the support layer 42 in the third direction (Z direction) perpendicular to the first direction (X direction). The inorganic patterns 49 may have the first critical dimension CD1 in the first direction (X direction). The inorganic patterns 49 may include line-type patterns LP1-2 on the support layer 42 in a plan view.

The space pattern 48 may be formed between each of the inorganic patterns 49 in the first direction (X direction) and may at least partially expose the support layer 42. The space patterns 48 may include line-type space patterns SP1-2 on the support layer 42 in a plan view. The space patterns 48 may have the second critical dimension CD2 in the first direction (X direction).

The inorganic patterns 49 and the space patterns 48 may be formed by using a plasma etching process on the third inorganic layer (47 in FIG. 10), the second inorganic layer (44-1 in FIG. 10), and the first inorganic layer (43 in FIG. 10) by using the plasma etching apparatus PTA of FIG. 1A or the plasma etching apparatus PTA-1 of FIG. 1B.

During the plasma etching process, an etching gas may be used to increase the etch selectivity of the third inorganic layer (47 in FIG. 10), the second inorganic layer (44-1 in FIG. 10), and the first inorganic layer (43 in FIG. 10) with respect to the organic mask patterns 46 and to reduce the global warming potential. That is, the etching gas favors etching of the third inorganic layer 47, the second inorganic layer 44-1, and the first inorganic layer 43 relative to the organic mask patterns 46. The etching gas may use a mixed gas using the C₂H₂F₄ gas as a main etching gas and the O₂ gas or an oxygen-containing gas as an auxiliary etching gas.

In some embodiments, the oxygen-containing gas may include CO₂, CO, COF₂, SO₂, H₂O, NO, NO₂, and/or N₂O. The oxygen-containing gas may not be limited to the molecular structure of the gases presented above, as long as the gases contain oxygen to generate oxygen plasma. In some embodiments, the plasma etching process may be performed by further including CF₄ gas, C₄F₈ gas, and/or Ar gas in a main etching gas.

The advantage of using the C₂H₂F₄ gas as the main etching gas is described above with reference to FIG. 5, and thus the same content thereof is omitted herein.

Additionally, when the C₂H₂F₄ gas is plasmaized, ratios of CF₃⁺, CF₂⁺, and CF⁺, which are etching species of the silicon oxide layer constituting the third inorganic layer (47 in FIG. 10) and the second inorganic layer (44-1 in FIG. 10), may be higher than ratios of CHF₂⁺ and CHF⁺, which are etching species of the SiN layer or the SiON layer constituting the first inorganic layer (43 in FIG. 10).

When configured in this manner, the etching speed of the third inorganic layer (47 in FIG. 10) and the second inorganic layer (44-1 on FIG. 10), which include the silicon oxide layer, and the etching speed of the first inorganic layer (43 in FIG. 10) including the SiN layer or the SiON layer may be controlled to be substantially uniform.

Accordingly, when C₂H₂F₄ gas is used as the etching gas during the plasma etching process, the etching selectivity defined as the ratio of the thickness T6 of the inorganic patterns 49 to the thickness T2 of the organic mask patterns 46 may be increased. That is, the etching gas favors etching of the inorganic patterns 49 relative to the organic mask patterns 46.

In addition, the advantage of using the O₂ gas as an auxiliary etching gas during the plasma etching process on the third inorganic layer (47 in FIG. 10), the second inorganic layer (44-1 in FIG. 10), and the first inorganic layer (43 in FIG. 10) is described in detail below.

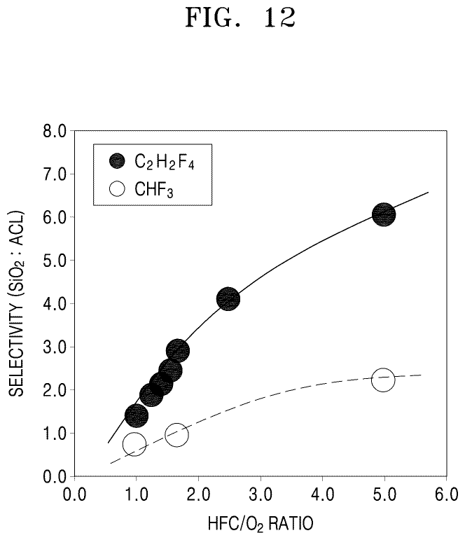

FIG. 12 is a diagram illustrating etching selectivities with respect to etching gases in a plasma etching process of an inorganic layer including a silicon oxide layer in a manufacturing method of a semiconductor device, according to some embodiments of the inventive concept.

As described above, according to some embodiments, a mixed gas may be used, which uses the C₂H₂F₄ gas (a hydrofluoric acid (HFC) gas) as the main etching gas and the O₂ gas or an oxygen-containing gas as the auxiliary etching gas when performing the plasma etching process on an inorganic layer including a silicon oxide layer.

In some embodiments, the oxygen-containing gas may include CO₂, CO, COF₂, SO₂, H₂O, NO, NO₂, and/or N₂0. The oxygen-containing gas may not be limited to the molecular structure of the gases presented above, as long as the gases contain oxygen to generate oxygen plasma. In some embodiments, the plasma etching process may be performed by further including CF₄ gas, C₄F₈ gas, and/or Ar gas in a main etching gas.

As described above, as a comparative example, when performing the plasma etching process on an inorganic layer including a silicon oxide layer, a mixed gas, which uses CHF₃ gas as a main etching gas and the O₂ gas as an auxiliary etching gas, may be used. In FIG. 12, the X-axis illustrates a mixing ratio of the C₂H₂F₄ gas (HFC gas) to the O₂ gas and a mixing ratio of the CHF₃ gas (HFC gas) to the O₂ gas.

FIG. 12 is a diagram of an etching selectivity of a silicon oxide layer with respect to organic mask patterns including an amorphous carbon layer (ACL) material. Accordingly, the Y-axis illustrates an etching selectivity of the silicon oxide layer with respect to the organic mask patterns including the ACL material.

In the present embodiment, it may be understood that as the mixing ratio of the C₂H₂F₄ gas (HFC gas) to the O₂ gas increases from about 1 to about 5, the etching selectivity increases from about 1 to about 6. To the contrary, in the comparative example, it may be understood that as the mixing ratio of the CHF₃ gas (HFC gas) to the O₂ gas increases from about 1 to about 5, the etching selectivity increases from about 1 to about 2.

Based on the result, when performing the plasma etching process on an inorganic layer including a silicon oxide layer as in the embodiment, using a mixed gas including the CHF₃ gas as a main etching gas and the O₂ gas as an auxiliary etching gas may better etch a silicon oxide layer without or with reduced damage to the organic mask pattern than the comparative example.

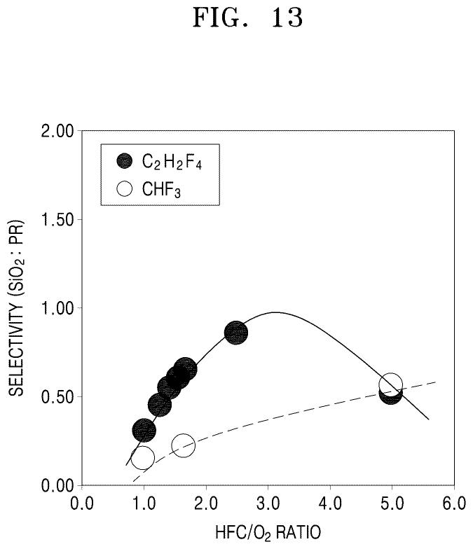

FIG. 13 is a diagram illustrating etching selectivities with respect to etching gases in a plasma etching process of an inorganic layer including a silicon oxide layer in a manufacturing method of a semiconductor device, according to some embodiments of the inventive concept.

The X-axis illustrates a mixing ratio of the C₂H₂F₄ gas (HFC gas) to the O₂ gas and a mixing ratio of the CHF₃ gas (HFC gas) to the O₂ gas. The Y-axis illustrates the etch selectivities of the silicon oxide layers with respect to the organic mask pattern including a photoresist (PR) material.

In the present embodiment, it may be understood that as the mixing ratio of the C₂H₂F₄ gas (HFC gas) to the O₂ gas increases from about 1 to about 3, the etching selectivity increases from about 0.3 to about 0.8. However, in the comparative example, it may be understood that as the mixing ratio of the CHF₃ gas (HFC gas) to the O₂ gas increases from about 1 to about 5, the etching selectivity increases from about 0.2 to about 0.5.

Based on the result, when performing the plasma etching process on an inorganic layer including a silicon oxide layer as in the embodiment, using a mixed gas including the CHF₃ gas as a main etching gas and the O₂ gas as an auxiliary etching gas may better etch a silicon oxide layer without or with reduced damage of the organic mask pattern than the comparative example.

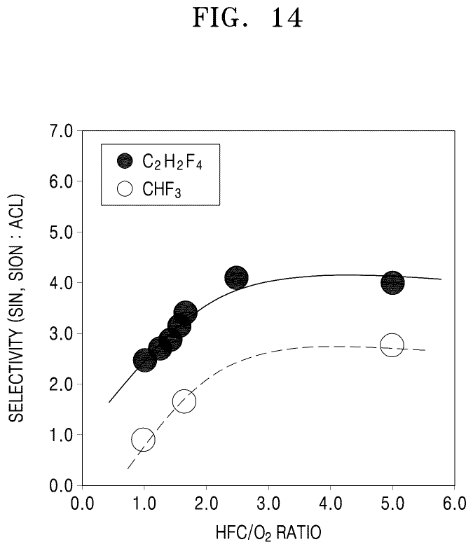

FIG. 14 is a diagram illustrating etching selectivities with respect to etching gases in a plasma etching process of an inorganic layer including the SiN layer or the SiON layer in a manufacturing method of a semiconductor device, according to some embodiments of the inventive concept.

The X-axis illustrates a mixing ratio of the C₂H₂F₄ gas (HFC gas) to the O₂ gas and a mixing ratio of the CHF₃ gas (HFC gas) to the O₂ gas. The Y-axis illustrates etching selectivities of the silicon nitride layers with respect to the organic mask patterns including the ACL material.

In the present embodiment, it may be understood that as the mixing ratio of the C₂H₂F₄ gas (HFC gas) to the O₂ gas increases from about 1 to about 5, the etching selectivity increases from about 2.5 to about 4.0. To the contrary, in the comparative example, it may be understood that as the mixing ratio of the CHF₃ gas (HFC gas) to the O₂ gas increases from about 1 to about 5, the etching selectivity increases from about 1.0 to about 2.9.

Based on the result, when performing the plasma etching process on an inorganic layer including the SiN layer or the SiON layer as in the embodiment, using a mixed gas including the C₂H₂F₄ gas as a main etching gas and the O₂ gas as an auxiliary etching gas may better etch the SiN layer without or with reduced damage of the organic mask pattern than the comparative example.

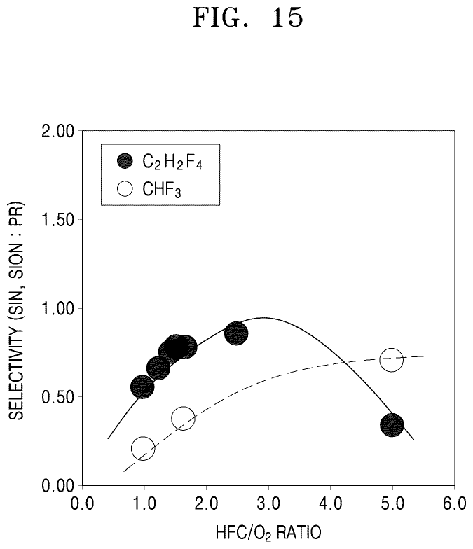

FIG. 15 is a diagram illustrating etching selectivities with respect to etching gases in a plasma etching process of an inorganic layer including a silicon nitride layer in a manufacturing method of a semiconductor device, according to some embodiments of the inventive concept.

The X-axis illustrates a mixing ratio of the C₂H₂F₄ gas (HFC gas) to the O₂ gas and a mixing ratio of the CHF₃ gas (HFC gas) to the O₂ gas. The Y-axis illustrates the etching selectivities of the silicon nitride layers with respect to the organic mask pattern including a PR material.

In the present embodiment, it may be understood that as the mixing ratio of the C₂H₂F₄ gas (HFC gas) to the O₂ gas increases from about 1 to about 2.5, the etching selectivity increases from about 0.5 to about 0.8. However, in the comparative example, it may be understood that as the mixing ratio of the CHF₃ gas (HFC gas) to the O₂ gas increases from about 1 to about 2.5, the etching selectivity increases from about 0.3 to about 0.7.

Based on the result, when performing the plasma etching process on an inorganic layer including the SiN layer or the SiON layer as in the embodiment, using a mixed gas including the C₂H₂F₄ gas (HFC gas) as a main etching gas and the O₂ gas as an auxiliary etching gas may better etch the SiN layer without or with reduced damage of the organic mask pattern than the comparative example.

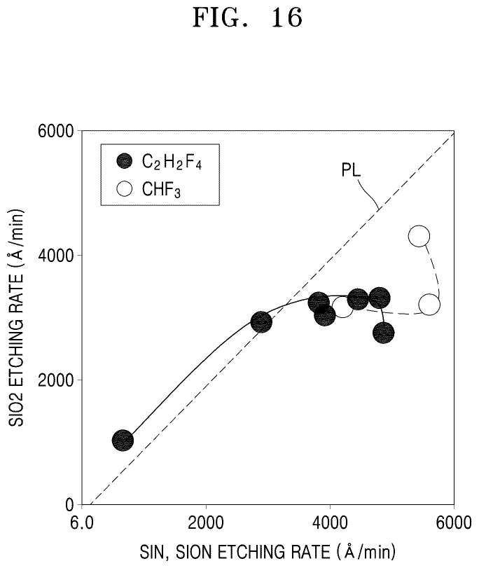

FIG. 16 is a diagram illustrating etching speeds with respect to etching gases in a plasma etching process of an inorganic layer including a silicon oxide layer, the SiN layer, or the SiON layer in a manufacturing method of a semiconductor device, according to some embodiments of the inventive concept.

The X-axis illustrates an etching speed of the SiN layer or the SiON layer. The Y-axis illustrates an etching speed of a silicon oxide (SiO₂) layer. When the C₂H₂F₄ gas is used as the etching gas as in the present embodiment, the etching speed of the SiO₂ layer may increase as the etching speed of the SiN layer or the SiON layer increases as indicated by a reference line PL. In other words, the etching speed of the SiN layer or the SiON layer and the etching speed of the SiO₂ layer may be increased by controlling them simultaneously or in concert with one another.

For example, when the C₂H₂F₄ gas is used as the etching gas, as the etching speed of the SiN layer or the SiON layer increases from about 200 A/min to about 4500 A/min, the etching speed of the SiO₂ layer may increase from about 200 A/min to about 3800 A/min.

On the other hand, in the comparative example, when the CHF₃ gas is used as the etching gas, the relationship between the etching speed of the SiN layer or the SiON layer and the etching speed of the SiO₂ layer may not be obtained. Based on the result, when performing the plasma etching process on an inorganic layer including the SiN layer or the SiON layer as in the embodiment, using a mixed gas including the C₂H₂F₄ gas as an etching gas may uniformly etch at the same etching speed the SiN layer or the SiON layer without or with reduced damage of the organic mask pattern than the comparative example.

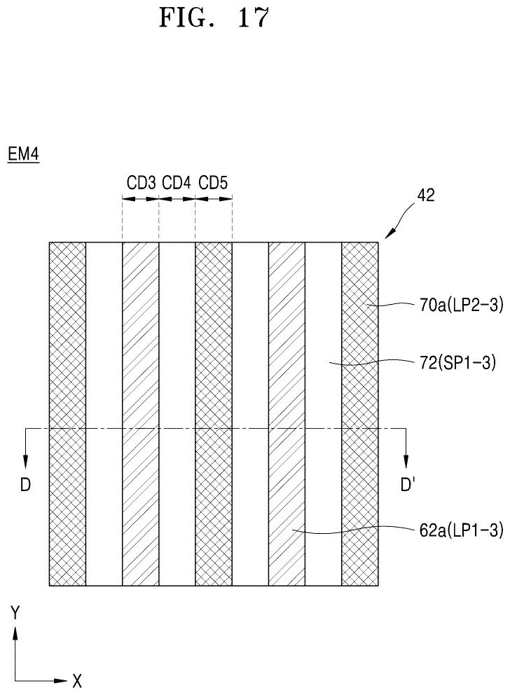

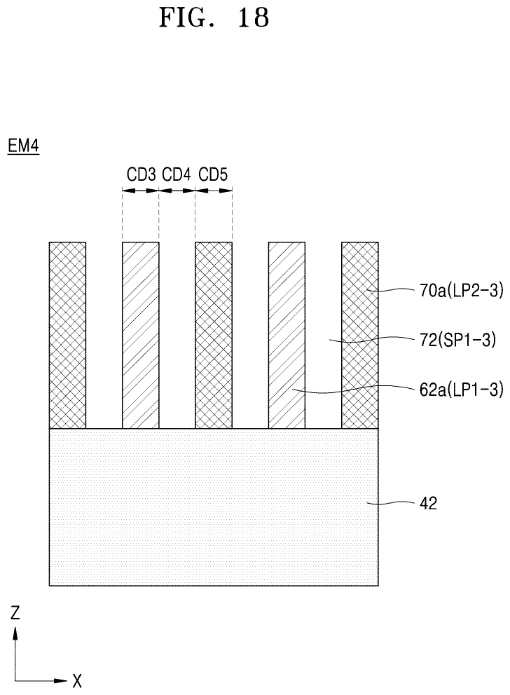

FIG. 17 is a plan view of a semiconductor device EM4 according to an embodiment, and FIG. 18 is a cross-sectional view of the semiconductor device EM4, taken along line D-D′in FIG. 17.

The semiconductor device EM4 may include first organic patterns 62a, second organic patterns 70a, and space patterns 72 arranged on the support layer 42. The first organic patterns 62a, the second organic patterns 70a, and the space patterns 72 may be formed by using the semiconductor device manufacturing method including the plasma etching process to be described below.

A manufacturing method of a semiconductor device may include a fine patterning process. The support layer 42 may include a substrate. The support layer 42 may correspond to the substrate 12 in FIGS. 1A and 1B. The support layer 42 may be formed by using the same material as described above.

The first organic patterns 62a may include a plurality of patterns apart from each other on the support layer 42 in the first direction (X direction). The first organic patterns 62a may have a third critical dimension CD3 in the first direction (X direction).

In some embodiments, the third critical dimension CD3 may be several nm to several tens of nm. In some embodiments, the third critical dimension CD3 may be about 20 nm or less. In some embodiments, the third critical dimension CD3 may range from 2 nm to 20 nm.

The first organic patterns 62a may, as illustrated in FIG. 17, include patterns extending in the second direction (Y direction) perpendicular to the first direction (X direction) in a plan view of the semiconductor device EM4. The first organic patterns 62a may, as illustrated in FIG. 18, include patterns extending in the third direction (Z direction) perpendicular to the first direction (X direction) in a plan view of the semiconductor device EM4. The first organic patterns 62a may include first line-type patterns LP1-3 in a plan view, as illustrated in FIG. 17.

The second organic patterns 70a may be arranged apart from the first organic patterns 62a by the space patterns 72 in the first direction (X direction). The second organic patterns 70a may include a plurality of patterns spaced apart from each other on the support layer 42 in the first direction (X direction). The second organic patterns 70a may, as illustrated in FIG. 18, include patterns extending in the third direction (Z direction) perpendicular to the first direction (X direction) in a plan view of the semiconductor device EM4.

The second organic patterns 70a may have a fifth critical dimension CD5 in the first direction (X direction). In some embodiments, the fifth critical dimension CD5 may be several nm to several tens of nm. In some embodiments, the fifth critical dimension CD5 may be about 20 nm or less. In some embodiments, the fifth critical dimension CD5 may range from 2 nm to 20 nm.

The second organic patterns 70a may, as illustrated in FIG. 17, include patterns extending in the second direction (Y direction) perpendicular to the first direction (X direction) in a plan view of the semiconductor device EM4. The second organic patterns 70a may, as illustrated in FIG. 18, include patterns extending in the third direction (Z direction) perpendicular to the first direction (X direction) in a plan view of the semiconductor device EM4. The second organic patterns 70a may include second linear patterns LP2-3 in a plan view of the semiconductor device EM4, as illustrated in FIG. 17.

The space patterns 72 may be arranged between the first organic patterns 62a and the second organic patterns 70a. The space patterns 72 may include a plurality of patterns spaced apart from each other on the support layer 42 in the first direction (X direction).

The space patterns 72 may have a fourth critical dimension CD4 in the first direction (X direction). In some embodiments, the fourth critical dimension CD4 may be several nm to several tens of nm. In some embodiments, the fourth critical dimension CD4 may be about 20 nm or less. In some embodiments, the fourth critical dimension CD4 may range from 2 nm to 20 nm.

The space patterns 72 may, as illustrated in FIG. 17, include patterns extending in the second direction (Y direction) perpendicular to the first direction (X direction) in a plan view of the semiconductor device EM4. The space patterns 72 may include line-type space patterns SP1-3 in a plan view of the semiconductor device EM4, as illustrated in FIG. 17. In some embodiments, the third critical dimension CD3 of the first organic patterns 62a, the fourth critical dimension CD4 of the second organic patterns 70a, and the fifth critical dimension CD5 of the space patterns 72 may be the same.

In some embodiments, the third critical dimension CD3 of the first organic patterns 62a, the fourth critical dimension CD4 of the second organic patterns 70a, and the fifth critical dimension CD5 of the space patterns 72 may be different from each other.

In some embodiments, the first organic patterns 62a and the second organic patterns 70a may include the same organic material. In some embodiments, the first organic patterns 62a and the second organic patterns 70a may include different organic materials from each other.

In some embodiments, the first organic patterns 62a and the second organic patterns 70a may include an SOH material. In this case, the SOH material may be referred to as a material including a hydrocarbon compound having a relatively high carbon content of about 85 wt % to about 99 wt % based on the total weight of carbon, or a material including derivatives of the hydrocarbon compound.

In some embodiments, the first organic patterns 62a and the second organic patterns 70a may include an ACL material or a PR material instead of the SOH material. The ACL material and the photoresist material may also contain a large amount of carbon, and thus they may have similar properties to the SOH material.

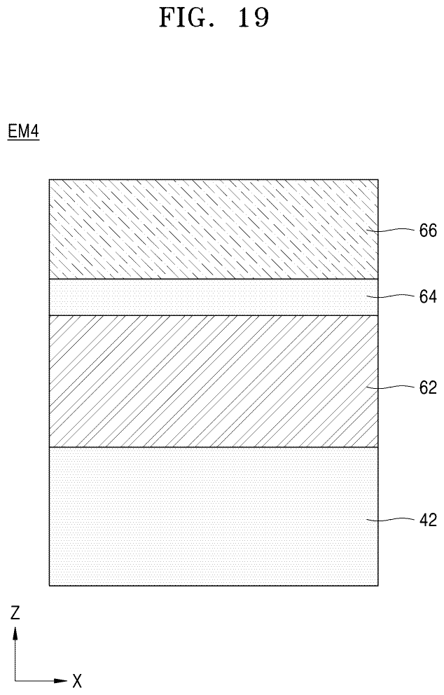

FIGS. 19 through 25 are diagrams illustrating a manufacturing method of the semiconductor device EM4, according to embodiments.

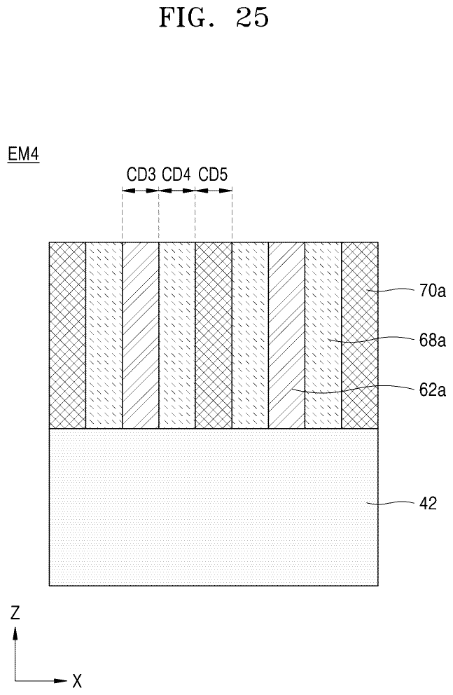

FIGS. 19 through 25 are provided to illustrate a manufacturing method of the semiconductor device EM4 of FIGS. 17 and 18. In FIGS. 19 and 25, descriptions given with reference to FIGS. 17 and 19 are briefly described or omitted.

Referring to FIG. 19, a first organic layer 62, a hard mask layer 64, and a PR layer 66 may be sequentially formed on a support layer 42. The support layer 42 may include a substrate, for example, a silicon substrate. The hard mask layer 64 may be formed of a silicon hard mask layer. The hard mask layer 64 and the PR layer 66 may be provided to pattern the first organic layer 62.

The first organic layer 62 may be formed by using an SOH material, an ACL material, or a PR material. For example, the first organic layer 62 include the SOH material may be formed by performing a bake process at least once, after doping an organic compound by using a spin coating process or another deposition process to form an organic compound layer.

The organic compound may include a hydrocarbon compound including an aromatic ring, such as phenyl, benzene, and naphthalene, or derivatives thereof. In addition, the organic compound may include a material having a relatively high carbon content of about 85% to about 99% by weight based on a total weight thereof.

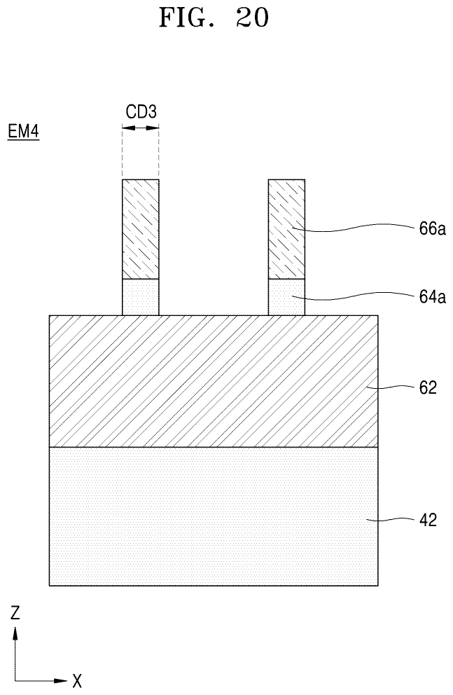

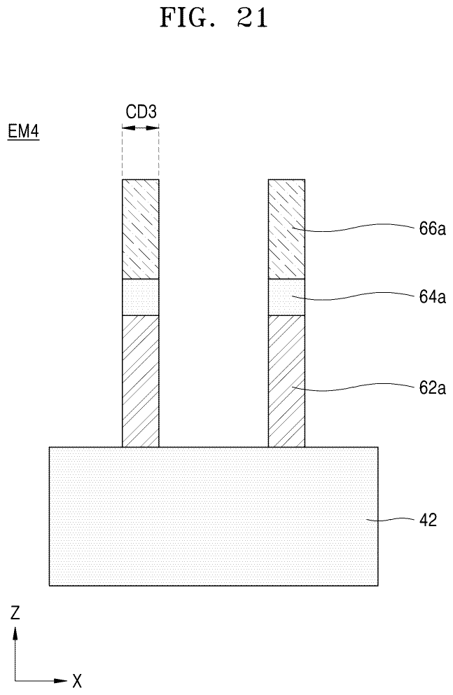

Referring to FIGS. 20 and 21, hard mask patterns 64a and PR patterns 66a may be formed on the first organic layer 62 as illustrated in FIG. 20. The PR patterns 66a may be formed by using a photolithography apparatus.

The hard mask patterns 64a may be formed by etching the hard mask layer 64 by using the PR patterns 66a as an etching mask. The hard mask patterns 64a and the PR patterns 66a may have the third critical dimension CD3 in the first direction (X direction).

As illustrated in FIG. 21, a plurality of first organic patterns 62a may be formed by etching the first organic layer (62 in FIG. 19) by using the PR patterns 66a as an etching mask. The first organic patterns 62a may be arranged apart from each other on the support layer 42 in the first direction (X direction). The first organic patterns 62a may be formed by using a patterning process on the first organic layer (62 in FIG. 19) as described above.

The first organic patterns 62a may be formed by using a patterning process on the first organic layer (62 in FIG. 19) firstly as described above. The first organic patterns 62a may have the third critical dimension CD3, like the hard mask patterns 64a and the PR patterns 66a.

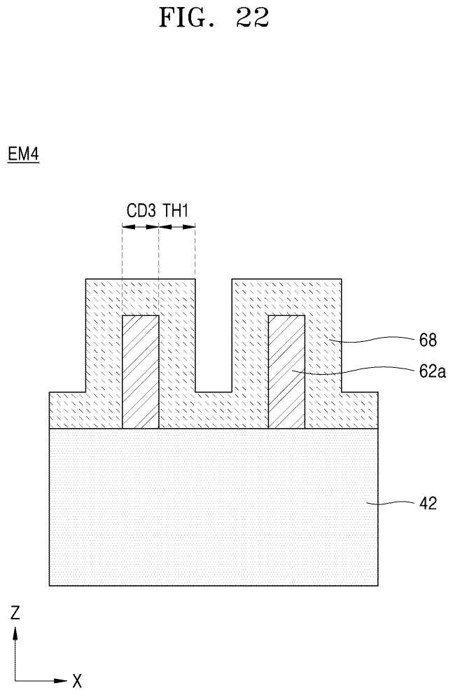

Referring to FIG. 22, the hard mask patterns (64a in FIG. 21) and the PR patterns (66a in FIG. 21) may be removed. The hard mask patterns (64a in FIG. 21) and the PR patterns (66a in FIG. 21) may be removed by using a wet etching process.

Subsequently, an inorganic layer 68 may be formed on the support layer 42 to be on and at least partially cover the first organic patterns 62a. The inorganic layer 68 may be formed on both sidewalls and an upper surface of the first organic patterns 62a, and on the support layer 42. The inorganic layer 68 may be formed to have a first thickness TH1.

The inorganic layer 68 may be formed on both sidewalls of the first organic patterns 62a to have the first thickness TH1. The first thickness TH1 may be several nm to tens of nm. The inorganic layer 68 may be formed on both sidewalls of the first organic patterns 62a and at the same time, may be formed not to fill spaces between each of the first organic patterns 62a.

In some embodiments, the inorganic layer 68 may include a silicon oxide layer. In some embodiments, the inorganic layer 68 may include the SiN layer and/or the SiON layer. The inorganic layer 68 may be formed by using a chemical vapor deposition method or an atomic layer deposition method.

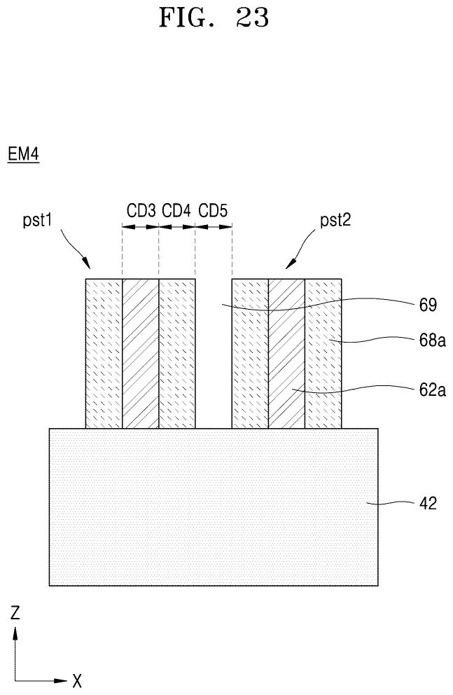

Referring to FIG. 23, the inorganic layer (68 in FIG. 22) may be etched back to form a plurality of inorganic patterns 68a. The inorganic layer (68 in FIG. 22) formed on the upper surfaces of the first organic patterns 62a and the inorganic layer (68 in FIG. 22) formed on the upper surface of the support layer 42 may be etched back and removed. The inorganic patterns 68a may be formed by patterning the inorganic layer (68 in FIG. 22) by using an etchback process.

The inorganic patterns 68a may be apart from each other in the first direction (X direction), while contacting both sidewalls of the first organic patterns 62a. The inorganic patterns 68a may be formed by being self-aligned with the first organic patterns 62a. The inorganic patterns 68a may also be referred to as inorganic spacer patterns.

The inorganic patterns 68a may have the fourth critical dimension CD4 in the first direction (X direction). The fourth critical dimension CD4 may be determined by the first thickness TH1 of the inorganic layer (68 in FIG. 22). The fourth critical dimension CD4 may be the same as the third critical dimension CD3.

Due to the etchback process of the inorganic layer (68 in FIG. 22), the first opening 69 may be formed between the inorganic patterns 68a. The first opening 69 may be formed by being self-aligned to the inorganic patterns 68a. The first opening 69 may have the fifth critical dimension CD5 in the first direction (X direction). The fifth critical dimension CD5 may be the same as the third critical dimension CD3 and the fourth critical dimension CD4.

According to the etchback process on the inorganic layer (68 in FIG. 22A), a first pattern structure pst1 including one first organic pattern 62a and two inorganic patterns 68a formed on both side walls of the first organic pattern 62a may be formed. According to the etchback process on the inorganic layer (68 in FIG. 22), a second pattern structure pst2 may be formed apart from the first pattern structure pst1 in the first direction (X direction).

The second pattern structure pst2 may include one first organic pattern 62a and two inorganic patterns 68a formed on both sidewalls of the first organic pattern 62a. The first opening 69 may be formed between the first pattern structure pst1 and the second pattern structure pst2.

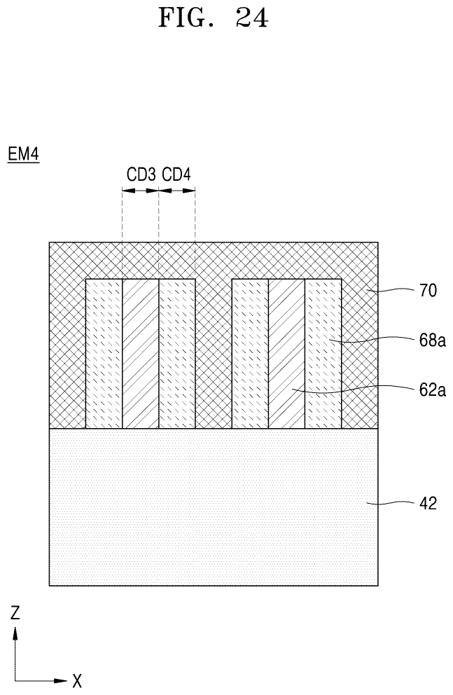

Referring to FIG. 24, a second organic layer 70 may be formed to be in and at least partially fill spaces between each of the inorganic patterns 68a while being on and at least partially covering the first organic patterns 62a and the inorganic patterns 68a. The second organic layer 70 may be formed on the first pattern structure pst1 and the second pattern structure pst2 while being in and at least partially filling the first opening 69.

The second organic layer 70 may be formed by using an SOH material, an ACL material, and/or a PR material. The second organic layer 70 may include the same material as or a different material from that of the first organic layer 62.

Referring to FIG. 25, the second organic layer (70 in FIG. 24) may be etched back to form a plurality of second organic patterns 70a. The second organic layer (70 in FIG. 24) formed on upper surfaces of the first organic patterns 62a and the inorganic patterns 68a may be etched back and removed.

The second organic patterns 70a may be formed between the inorganic patterns 68a and at the same time, may be spaced apart from each other in the first direction (X direction). The second organic patterns 70a may have the fifth critical dimension CD5 in the first direction (X direction). The fifth critical dimension CD5 of the second organic patterns 70a may be the same as the third critical dimension CD3 and the fourth critical dimension CD4.

Subsequently, as illustrated in FIG. 18, the inorganic patterns (68a in FIG. 17) may be selectively etched and removed on the support layer 42. The inorganic patterns (68a of FIG. 17) may be selectively removed by performing the plasma etching process with the etching selectivity of the inorganic patterns (68 in FIG. 17) being greater than the etching selectivities of the first organic patterns 62a and the second organic patterns 70a. That is, the etching gas favors etching of the inorganic patterns 68a relative to the first organic patterns 62a and the second organic patterns 70a.

As described above, the inorganic patterns (68a in FIG. 17) may be etched by using a mixed gas using an etching gas, that is, the C₂H₂F₄ gas as a main etching gas, and the O₂ gas or an oxygen-containing gas as an auxiliary etching gas.

In some embodiments, the oxygen-containing gas may include CO₂, CO, COF₂, SO₂, H₂O, NO, NO₂, and/or N₂O. The oxygen-containing gas may not be limited to the molecular structure of the gases presented above, as long as the gases contain oxygen to generate oxygen plasma.

In some embodiments, the plasma etching process may be performed by further including CF₄ gas, C₄F₈ gas, and/or Ar gas in a main etching gas. The etching selectivity of the layers during the plasma etching process has been described with reference to FIGS. 12 through 15, and thus a description thereof is omitted.

As the inorganic patterns (68a in FIG. 17) are removed, the first organic patterns 62a and the second organic patterns 70a may become the first line-type patterns LP1-3 and the second line-type patterns LP2-3, respectively.

As the inorganic patterns (68a in FIG. 17) are removed, a plurality of space patterns 72 may be formed between the first organic patterns 62a and the second organic patterns 70a. The space patterns 72 may become the line-type space patterns SP1-3. The space patterns 72 may have the fourth critical dimension CD4 in the first direction (X direction).

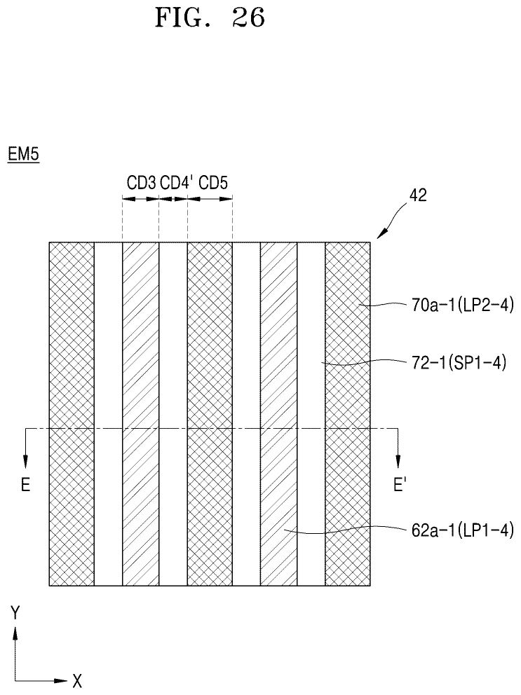

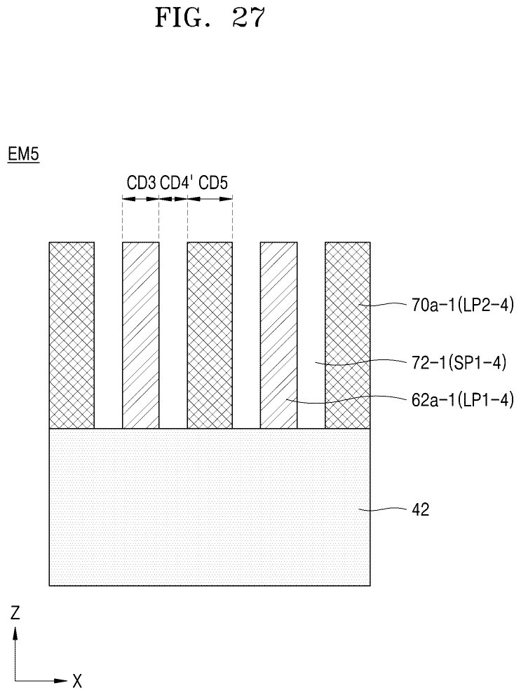

FIG. 26 is a plan view of a semiconductor device EM5 according to an embodiment, and FIG. 27 is a cross-sectional view of the semiconductor device EM5, taken along line E-E′ in FIG. 27.

The semiconductor device EM5 may be the same as the semiconductor device EM4 of FIGS. 17 and 18 except that the critical dimensions of space patterns 72-1 and first organic patterns 62a-1 are different. In FIGS. 26 and 27, descriptions given with reference to FIGS. 17 and 19 are briefly described or omitted.

The semiconductor device EM5 may include the first organic patterns 62a-1, second organic patterns 70a-1, and space patterns 72-1 arranged on the support layer 42. The first organic patterns 62a-1 may include a plurality of patterns spaced apart from each other on the support layer 42 in the first direction (X direction).

The first organic patterns 62a-1 may include first line-type patterns LP1-4 in a plan view of the semiconductor device EM5, as illustrated in FIG. 26. The first organic patterns 62a-1 may, as illustrated in FIG. 27, include patterns extending in the third direction (Z direction) perpendicular to the first direction (X direction) in a plan view of the semiconductor device EM5.

The first organic patterns 62a-1 may have the third critical dimension CD3 in the first direction (X direction). In some embodiments, the third critical dimension CD3 may be several nm to several tens of nm. In some embodiments, the third critical dimension CD3 may be about 20 nm or less. In some embodiments, the third critical dimension CD3 may range from 2 nm to 20 nm.

The second organic patterns 70a-1 may be arranged spaced apart from the first organic patterns 62a by the space patterns 72-1 in the first direction (X direction). The second organic patterns 70a-1 may include second line-type patterns LP2-4 in a plan view of the semiconductor device EM5, as illustrated in FIG. 26. The second organic patterns 70a-1 may, as illustrated in FIG. 27, include patterns extending in the third direction (Z direction) perpendicular to the first direction (X direction) in a plan view of the semiconductor device EM5.

The second organic patterns 70a-1 may have the fifth critical dimension CD5 in the first direction (X direction). The fifth critical dimension CD5 may be greater than the third critical dimension CD3. In some embodiments, the fifth critical dimension CD5 may be several nm to several tens of nm. In some embodiments, the fifth critical dimension CD5 may be about 20 nm or less. In some embodiments, the fifth critical dimension CD5 may range from 2 nm to 20 nm.

The space patterns 72-1 may be arranged between the first organic patterns 62a-1 and the second organic patterns 70a-1. The space patterns 72-1 may include line-type space patterns SP1-4 in a plan view of the semiconductor device EM5, as illustrated in FIG. 26. The space patterns 72-1 may have a fourth critical dimension CD4′ in the first direction (X direction). The fourth critical dimension CD4′ may be less than the third critical dimension CD3.

In some embodiments, the fourth critical dimension CD4′ may be several nm to several tens of nm. In some embodiments, the fourth critical dimension CD4′ may be about 20 nm or less. In some embodiments, the fourth critical dimension CD4′ may range from 2 nm to 20 nm.

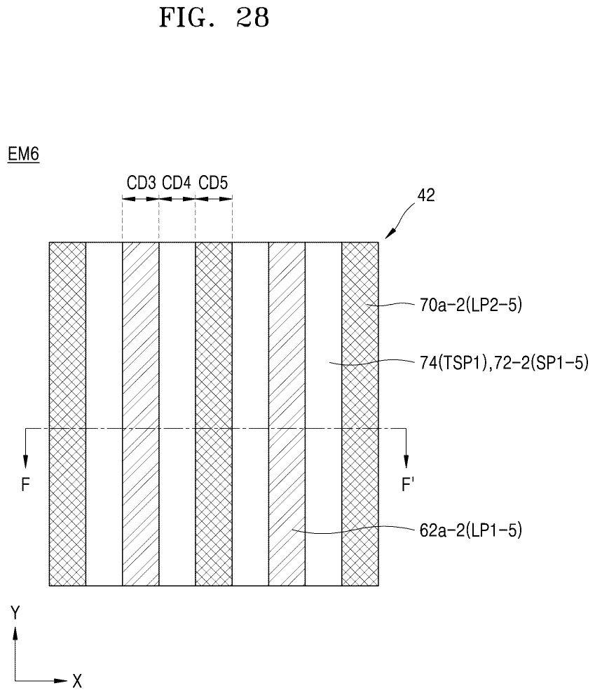

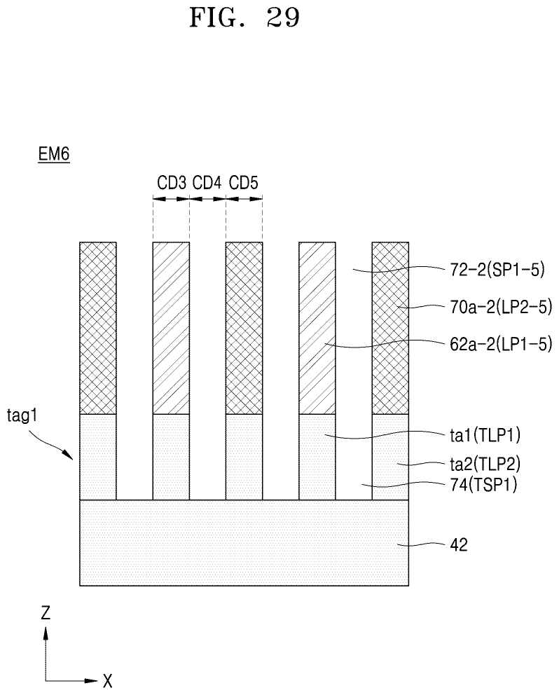

FIG. 28 is a plan view of a semiconductor device EM6 according to an embodiment, and FIG. 29 is a cross-sectional view of the semiconductor device EM6, taken along line F-F′ in FIG. 28.

The semiconductor device EM6 may, when compared to the semiconductor device EM4 of FIGS. 17 and 18, be the same except that trench patterns 74 are further formed between first organic patterns 62a-2 and second organic patterns 70a-2. In FIGS. 28 and 29, descriptions given with reference to FIGS. 17 and 19 are briefly described or omitted.

The semiconductor device EM6 may include the first organic patterns 62a-2, second organic patterns 70a-2, and space patterns 72-2, and the trench patterns 74 arranged on the support layer 42. The first organic patterns 62a-2 may include first line-type patterns LP1-5 in a plan view of the semiconductor device EM6, as illustrated in FIG. 28. The second organic patterns 70a-2 may include second line-type patterns LP2-5 in a plan view of the semiconductor device EM6, as illustrated in FIG. 28.

The space patterns 72-2 and the trench patterns 74 may be arranged between the first organic patterns 62a-2 and the second organic patterns 70a-2. The space patterns 72-2 and the trench patterns 74 may include a plurality of patterns spaced apart from each other in the first direction (X direction) and extending in the second direction (Y direction) on the support layer 42.

The space patterns 72-2 may include line-type space patterns SP1-5 in a plan view, as illustrated in FIG. 28. The trench patterns 74 may include line-type trench patterns TSP1 in a plan view of the semiconductor device EM6, as illustrated in FIG. 28.

As illustrated in FIG. 29, the trench patterns 74 may be formed by etching a target layer tag1, which is a portion of the support layer 42, by using the first organic patterns 62a-2 and the second organic patterns 70a-2 as masks. The trench patterns 74 may have the same fourth critical dimension CD4 as the space patterns 72-2.

As the trench patterns 74 are formed, the target layer tag1 may, as illustrated in FIG. 29, include first target patterns ta1 under the first organic patterns 62a-2 and second target patterns ta2 under the second organic patterns 70a-2. The first target patterns ta1 and the second target patterns ta2 may include the same material as the support layer 42.

The first target patterns ta1 may include first line-type target patterns TLP1 extending in the second direction (Y direction). The second target patterns ta2 may include second line-type target patterns TLP2 extending in the second direction (Y direction).

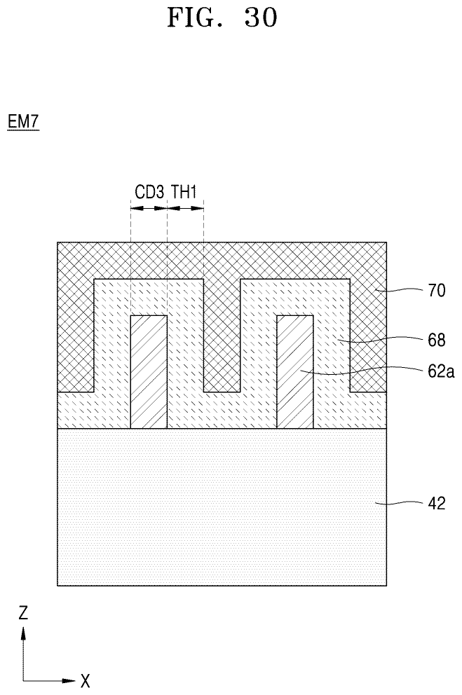

FIGS. 30 through 32 are cross-sectional views for describing a manufacturing method of a semiconductor device EM7, according to embodiments.

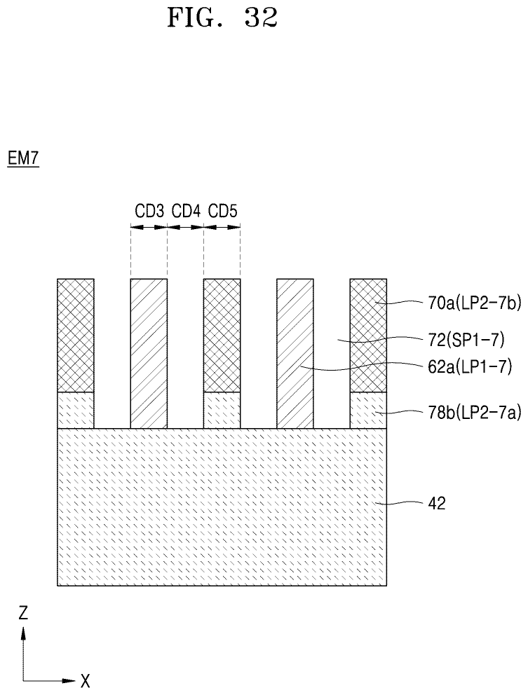

The manufacturing method of the semiconductor device EM7 of FIGS. 30 through 32 may, when compared to the manufacturing method of the semiconductor device EM4 of FIGS. 19 through 25, be the same except that the first organic layer (62 in FIG. 19) and the second organic layer (70 in FIG. 24) are formed with different materials and a sequence of the etchback process is changed. In FIGS. 30 and 32, descriptions given with reference to FIGS. 19 through 25 are briefly described or omitted.

Referring to FIG. 30, firstly, the manufacturing process of FIGS. 19 through 22 may be performed. During the manufacturing process of FIGS. 19 through 22, the first organic layer (62 in FIG. 19) may be formed by using an SOH material, an ACL material, and/or a PR material.

In the present embodiment, the first organic layer (62 in FIG. 19) may include an SOH material. By performing the manufacturing process of FIGS. 19 through 22, the first organic patterns 62a may have the third critical dimension CD3, and the inorganic layer 68 may be formed on the first organic patterns 62a at the first thickness TH1.

Next, the second organic layer 70 may be formed on the support layer 42 to be in and at least partially fill the spaces between each of the first organic patterns 62a while being on and at least partially covering the first organic patterns 62a and the inorganic layer 68. The second organic layer 70 may be formed to be in and at least partially fill the spaces between each of the first organic patterns 62a on the inorganic layer 68. The second organic layer 70 may include a material different from that of the first organic layer (62 in FIG. 19) or the first organic patterns 62a.

The second organic layer 70 may be formed by using an SOH material, an ACL material, or a PR material. In the present embodiment, the second organic layer 70 may include an ACL material.

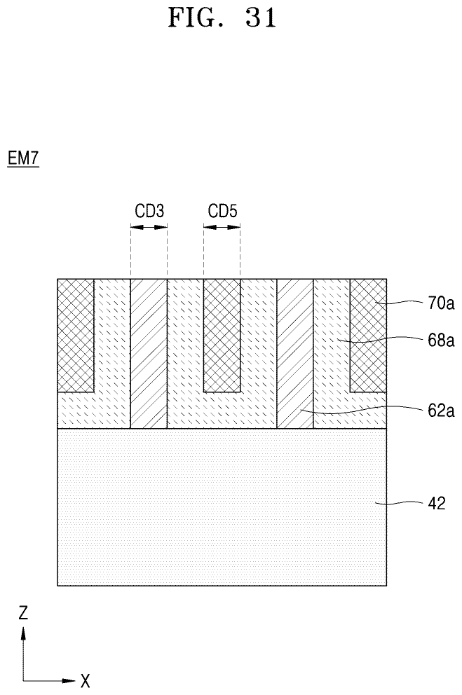

Referring to FIG. 31, the second organic layer (70 in FIG. 30) may be etched back to form the plurality of second organic patterns 70a. The inorganic layer 68 may be etched back to form the plurality of inorganic patterns 68a. The second organic layer (70 in FIG. 30) and the inorganic layer 68 may be sequentially etched back.

The second organic patterns 70a may have the fifth critical dimension CD5. The second organic patterns 70a may be between the inorganic patterns 68a. The inorganic patterns 68a may be between the first organic patterns 62a and the second organic patterns 70a.

Referring to FIG. 32, the inorganic patterns 68a between the first organic patterns 62a and the second organic patterns 70a may be selectively removed on the support layer 42. The inorganic patterns 68a between the first organic patterns 62a and the second organic patterns 70a may be selectively removed by performing the plasma etching on the inorganic patterns 68a with the etching selectivity of the inorganic patterns 68a greater than those of the first organic patterns 62a and the second organic patterns 70a. That is, the etching gas favors etching of the inorganic patterns 68a relative to the first organic patterns 62a and the second organic patterns 70a.

As described above, the inorganic patterns 68a between the first organic patterns 62a and the second organic patterns 70a may be etched by using a mixed gas using an etching gas, for example, the C₂H₂F₄ gas as a main etching gas, and the O₂ gas or an oxygen-containing gas as an auxiliary etching gas.

In some embodiments, the oxygen-containing gas may include CO₂, CO, COF₂, SO₂, H₂O, NO, NO₂, and/or N₂O. The oxygen-containing gas may not be limited to the molecular structure of the gases presented above, as long as the gases contain oxygen to generate oxygen plasma. In some embodiments, the plasma etching process may be performed by further including CF₄ gas, C₄F₈ gas, and/or Ar gas in a main etching gas. The etching selectivity of the layers during the plasma etching process has been described with reference to FIGS. 12 through 15, and thus a description thereof is omitted.

The plurality of space patterns 72 may be formed between the first organic patterns 62a and the second organic patterns 70a. When the inorganic patterns 68a between the first organic patterns 62a and the second organic patterns 70a are selectively removed, lower inorganic patterns 78b may remain under the second organic patterns 70a.

The space patterns 72 may become line-type space patterns SP1-7. The space patterns 72 may have the fourth critical dimension CD4. The first organic patterns 62a may become first line-type patterns LP1-7. The second organic patterns 70a and the lower inorganic patterns 78b may become second line-type patterns LP2-7a and LP2-7b. The second organic patterns 70a may have the fifth critical dimension CD5.

While the inventive concept has been particularly shown and described with reference to embodiments thereof, it will be understood that various change in form and details may be made therein without departing from the spirit and scope of the following claims.

What is claimed is:

1. A manufacturing method of a semiconductor device, the manufacturing method comprising:
forming an inorganic layer on a support layer;
forming organic mask patterns on the inorganic layer; and
forming inorganic patterns and space patterns configured to at least partially expose the support layer between the inorganic patterns by performing a plasma etching process on the inorganic layer with the organic mask patterns as an etching mask,
wherein the plasma etching process has an etching selectivity that favors the inorganic layer relative to the organic mask patterns, and
wherein the plasma etching process on the inorganic layer is performed by using a mixed gas comprising C₂H₂F₄ gas as a main etching gas and O₂ gas or an oxygen-containing gas as an auxiliary etching gas, and a ratio of the main etching gas to the auxiliary etching gas is configured as about 1 to about 5.

2. The manufacturing method of claim 1, wherein the inorganic layer comprises a single monolithic layer including a silicon oxide layer, or a single monolithic layer including a silicon nitride layer or a silicon oxynitride layer.

3. The manufacturing method of claim 1, wherein the inorganic layer comprises a double layer including a first layer comprising a silicon oxide layer and a second layer comprising a silicon nitride layer or the second layer comprising a silicon oxynitride layer.

4. The manufacturing method of claim 1, wherein the inorganic layer comprises a triple layer including a first layer comprising a silicon nitride layer or a silicon oxynitride layer, a second layer comprising a first silicon oxide layer, and a third layer comprising a second silicon oxide layer.

5. The manufacturing method of claim 1, wherein the oxygen-containing gas comprises CO₂, CO, COF₂, SO₂, H₂O, NO, NO₂, or N₂O or any combination thereof.

6. The manufacturing method of claim 1, wherein the plasma etching process is performed by further using a CF₄ gas, a C₄F₈ gas, and an Ar gas, in addition to the main etching gas.

7. The manufacturing method of claim 1, wherein the organic mask patterns comprise a spin-on hard mask (SOH) material, an amorphous carbon layer (ACL) material, or a photoresist material.

8. The manufacturing method of claim 1, wherein critical dimensions of the inorganic patterns and the space patterns are identical.

9. The manufacturing method of claim 1, wherein the inorganic patterns and the space patterns form line-type patterns in a plan view of the semiconductor device.

10. A method of manufacturing a semiconductor device, the method comprising:
forming a first organic layer on a support layer;
forming first organic patterns by patterning the first organic layer;
forming an inorganic layer on the first organic patterns on the support layer;
forming inorganic patterns on both sidewalls of the first organic patterns by performing an etchback process on the inorganic layer;
forming a second organic layer in spaces between each of the inorganic patterns while being on the first organic patterns and the inorganic patterns;
forming second organic patterns between the inorganic patterns by performing an etchback process on the second organic layer; and
forming space patterns between the first organic patterns and the second organic patterns by selectively removing the inorganic patterns between the first organic patterns and the second organic patterns by performing a plasma etching process on the inorganic patterns,
wherein the plasma etching process has an etching selectivity that favors the inorganic patterns relative to the first organic patterns and the second organic patterns, and
wherein the plasma etching process on the inorganic patterns is performed by using a mixed gas comprising C₂H₂F₄ gas as a main etching gas and O₂ gas or an oxygen-containing gas as an auxiliary etching gas, and a ratio of the main etching gas to the auxiliary etching gas is configured as about 1 to about 5.

11. The manufacturing method of claim 10, wherein the patterning of the first organic patterns comprises:
forming sequentially hard mask patterns and photoresist patterns on the first organic layer;
forming first organic patterns by etching the first organic layer by using the hard mask patterns and the photoresist patterns as an etching mask; and
removing the hard mask patterns and the photoresist patterns.

12. The manufacturing method of claim 10, wherein the inorganic layer comprises a silicon oxide layer, a silicon nitride layer, or a silicon oxynitride layer.

13. The manufacturing method of claim 10, wherein the first organic layer and the second organic layer comprise a spin-on hard mask (SOH) material, an amorphous carbon layer (ACL) material, or a photoresist material.

14. The manufacturing method of claim 10, wherein the first organic layer and the second organic layer comprise different materials from each other.

15. The manufacturing method of claim 10, wherein critical dimensions of the first organic patterns, the second organic patterns, and the space patterns are identical to each other.

16. The manufacturing method of claim 10, wherein critical dimensions of the space patterns are less than those of the first organic patterns and the second organic patterns.

17. The manufacturing method of claim 10, wherein trench patterns are formed by further etching a portion of the support layer by using the first organic patterns and the second organic patterns as an etching mask.

18. A method of manufacturing a semiconductor device, the method comprising:
forming a first organic layer on a support layer;
forming first organic patterns by patterning the first organic layer;
forming an inorganic layer on the first organic patterns on the support layer;
forming a second organic layer in spaces between each of the first organic patterns while being on the first organic patterns and the inorganic layer on the support layer;
forming inorganic patterns and second organic patterns by sequentially etching back the second organic layer and the inorganic layer, wherein the second organic patterns are formed between the inorganic patterns, and the inorganic patterns are formed between the first organic patterns and the second organic patterns; and
forming space patterns between the first organic patterns and the second organic patterns by selectively removing the inorganic patterns between the first organic patterns and the second organic patterns by performing a plasma etching process on the inorganic patterns,
wherein the plasma etching process has an etching selectivity that favors the inorganic patterns relative to the first organic patterns and the second organic patterns, and
wherein the plasma etching process on the inorganic patterns is performed by using a mixed gas comprising C₂H₂F₄ gas as a main etching gas and O₂ gas or an oxygen-containing gas as an auxiliary etching gas, and a ratio of the main etching gas to the auxiliary etching gas is configured as about 1 to about 5.

19. The manufacturing method of claim 18, wherein, when the inorganic patterns between the first organic patterns and the second organic patterns are selectively removed by using the plasma etching process, lower inorganic patterns remain under the second organic patterns.

20. The manufacturing method of claim 18, wherein the inorganic layer comprises a silicon oxide layer, a silicon nitride layer, or a silicon oxynitride layer, and the first organic layer and the second organic layer comprise a spin on hard mask (SOH) material, an amorphous carbon layer (ACL) material, or a photoresist material, and
wherein the first organic patterns, the second organic patterns, and the space patterns form line-type patterns in a plan view of the semiconductor device.
